(19) United States
(12) Patent Application Publication
(10) Pub. No.: US 2024/0365567 A1
(43) Pub. Date: Oct. 31, 2024

(54) SEMICONDUCTOR DEVICE AND ELECTRONIC SYSTEM INCLUDING THE SAME

(71) Applicant: Samsung Electronics Co., Ltd., Suwon-si (KR)

(72) Inventors: Jinwoo Lee, Suwon-si (KR); Dongho Ahn, Suwon-si (KR); Jin Myung Choi, Suwon-si (KR)

(21) Appl. No.: 18/471,585

(22) Filed: Sep. 21, 2023

(30) Foreign Application Priority Data
Apr. 26, 2023 (KR) 10-2023-0055040

(51) Int. Cl. H10B 63/00

(52) U.S. Cl. CPC H10B 63/845; H10B 63/34

(57) ABSTRACT

A semiconductor device according to an embodiment includes a gate stack structure and a channel structure. The gate stack structure includes a plurality of gate electrodes and a plurality of insulating layers alternately stacked on a substrate in a first direction perpendicular to an upper surface of the substrate. The channel structure includes a portion penetrating through the gate stack structure and extending in the first direction. The channel structure includes a channel layer, a resistance change layer, and a metal-containing layer sequentially stacked. The metal-containing layer includes a metal or a metal compound.

### CROSS-REFERENCE TO RELATED APPLICATION

This application claims priority to and the benefit under 35 U.S.C. § 119 of Korean Patent Application No. 10-2023-0055040 filed in the Korean Intellectual Property Office on Apr. 26, 2023, the entire contents of which are incorporated herein by reference.

### BACKGROUND

The present disclosure relates to a semiconductor device and an electronic system including the same.

For an electronic system that needs to store data, there has been a demand for a semiconductor device capable of storing high-capacity data. Accordingly, methods for increasing the data storage capacity of the semiconductor device are being studied. For example, as one of the methods for increasing the data storage capacity of the semiconductor device, it has been proposed that the semiconductor device includes three-dimensionally arranged memory cells rather than two-dimensionally arranged memory cells.

### SUMMARY

The present disclosure attempts to provide a semiconductor device capable of improving performance and efficiency, and an electronic system including the same.

According to an embodiment of the present disclosure, a semiconductor device includes a gate stack structure and a channel structure. The gate stack structure includes a plurality of gate electrodes and a plurality of insulating layers alternately stacked on a substrate in a first direction perpendicular to an upper surface of the substrate. The channel structure includes a portion penetrating through the gate stack structure and extending in the first direction. The channel structure includes a channel layer, a resistance change layer, and a metal-containing layer sequentially stacked. The metal-containing layer includes a metal or a metal compound.

According to another embodiment of the present disclosure, a semiconductor device includes a resistive random access memory cell including a gate stack structure and a channel structure. The gate stack structure includes a plurality of gate electrodes and a plurality of insulating layers alternately stacked on a substrate in a first direction perpendicular to an upper surface of the substrate. The channel structure includes a portion penetrating through the gate stack structure and extending in the first direction. The channel includes a channel layer, a resistance change layer, and an oxygen-vacancy donor layer sequentially stacked. The oxygen-vacancy donor layer is configured to receive oxygen from the resistance change layer and to provide oxygen vacancies to the resistance change layer to control the oxygen vacancies in the resistance change layer.

According to another embodiment of the present disclosure, an electronic system includes a main board, the above-described semiconductor device disposed on the main board, and a controller electrically connected to the semiconductor device on the main board.

According to the embodiments, since the memory cell is configured as a resistive random access memory cell, it is possible to prevent interference between neighboring memory cells. Accordingly, the thickness of the gate electrode can be reduced, thereby increasing the number of gate electrodes and increasing the capacity (i.e., density) of the memory.

In this case, by placing the metal-containing layer on the resistance change layer, oxygen can be induced to move from the resistance change layer to the metal-containing layer, thereby controlling oxygen vacancies in the resistance change layer. In addition, the thickness of the resistance change layer can be adjusted by adjusting the thickness of the metal-containing layer. Therefore, properties of the memory cell can be effectively controlled by the metal-containing layer, and performance and efficiency of the semiconductor device can be effectively improved with a simple structure. In addition, the semiconductor device having excellent performance and efficiency can be formed through a simple process.

### BRIEF DESCRIPTION OF THE DRAWINGS

FIG. 1 is a schematic cross-sectional view illustrating at least a portion of an example semiconductor device according to an embodiment.

FIG. 2 is a partial cross-sectional view illustrating an example of a channel structure included in the semiconductor device illustrated in FIG. 1.

FIG. 3 is an enlarged partial cross-sectional view illustrating portion A of FIG. 2

FIGS. 4A and 4B are graphs illustrating oxygen contents along line B-B′ and line C-C′, respectively, of FIG. 3.

FIGS. 5A to 5D are diagrams for conceptually explaining an example method of driving the semiconductor device illustrated in FIG. 1.

FIGS. 6A to 6F are partial cross-sectional views illustrating intermediate processes in an example method of manufacturing the semiconductor device according to an embodiment.

FIG. 7 is an enlarged partial cross-sectional view illustrating a partial portion of a semiconductor device according to another embodiment.

FIG. 8 is an enlarged partial cross-sectional view illustrating a partial portion of a semiconductor device according to another embodiment.

FIG. 9 is a schematic cross-sectional view illustrating at least a portion of an example semiconductor device according to an additional embodiment.

FIG. 10 is an enlarged partial cross-sectional view illustrating portion D of FIG. 9.

FIG. 11 is a schematic diagram illustrating an electronic system including a semiconductor device according to an embodiment.

FIG. 12 is a schematic perspective view illustrating an electronic system including a semiconductor device according to an embodiment.

FIG. 13 is a schematic cross-sectional view illustrating a semiconductor package according to an embodiment.

FIG. 14 is a schematic cross-sectional view illustrating a semiconductor package according to an embodiment.

### DETAILED DESCRIPTION

Hereinafter, various embodiments of the present disclosure will be described in detail with reference to the accompanying drawings so that they can be easily carried out by those having ordinary knowledge in the art to which the present disclosure pertains. The present disclosure may be embodied in many different forms, and is not limited to the embodiments described herein.

In order to clearly describe the present disclosure, parts irrelevant to the description will be omitted, and the same or similar components will be denoted by the same reference signs throughout the specification.

In addition, the size and thickness of each component illustrated in the drawings are arbitrary for convenience of description, and the present disclosure is not necessarily limited to what is illustrated in the drawings. In order to clearly express several layers and regions in the drawings, their thicknesses may be enlarged. In addition, for convenience of explanation, thicknesses of some layers and regions may be exaggerated in the drawings.

In addition, when a part such as a layer, a film, a region, or a plate is referred to as being “on” another part, it may be “directly on” the other part or there may be an intervening part therebetween. In contrast, when a part is referred to as being “directly on” another part, there is no intervening part therebetween. In addition, when a part is referred to as being “on” a reference part, it is positioned on or under the reference part, and does not necessarily mean that it is positioned “on” the reference part in the opposite direction of gravity.

In addition, when a certain part is referred to as “comprising” or “including” a certain component throughout the specification, this implies the presence of the certain component, not precluding the presence of other components, unless explicitly stated to the contrary.

In addition, throughout the specification, the phrase “in a plan view” means when a target part is viewed from above, the phrase “in a cross-sectional view” means when a cross section of a target part as vertically cut is viewed laterally.

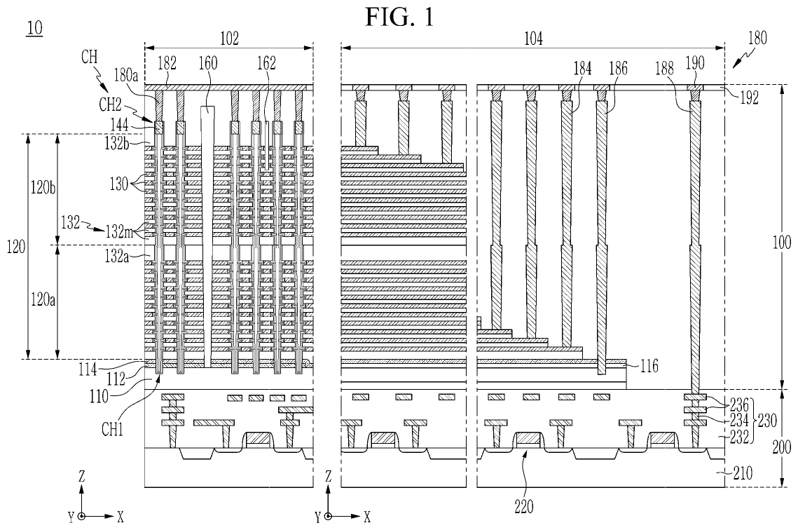

Hereinafter, a semiconductor device and a method for manufacturing the same according to an embodiment will be described in detail with reference to FIGS. 1 to 5 and FIGS. 6A to 6F.

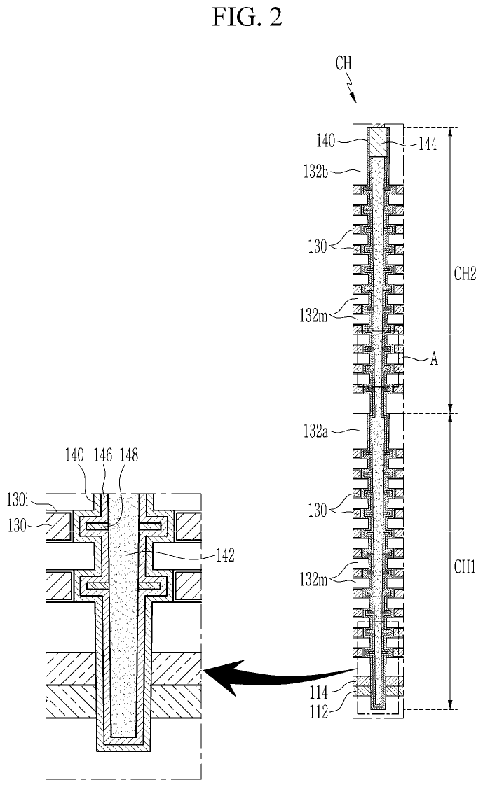

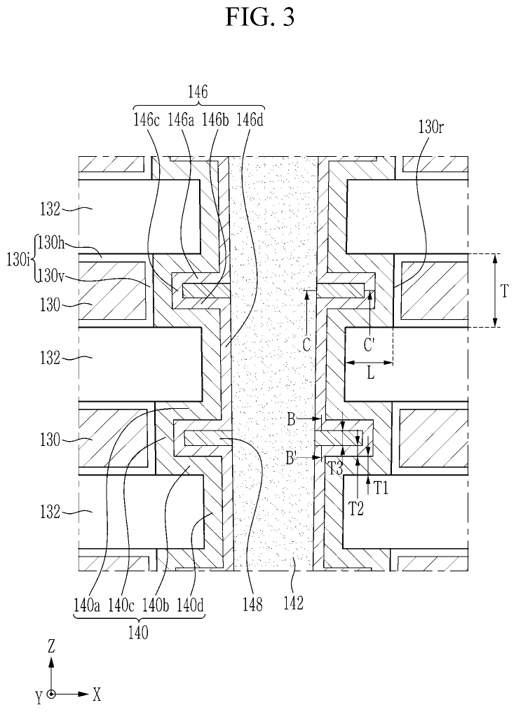

FIG. 1 is a schematic cross-sectional view illustrating at least a portion of an example semiconductor device according to an embodiment. FIG. 2 is a partial cross-sectional view illustrating an example of a channel structure included in the semiconductor device illustrated in FIG. 1. FIG. 3 is an enlarged partial cross-sectional view illustrating portion A of FIG. 2.

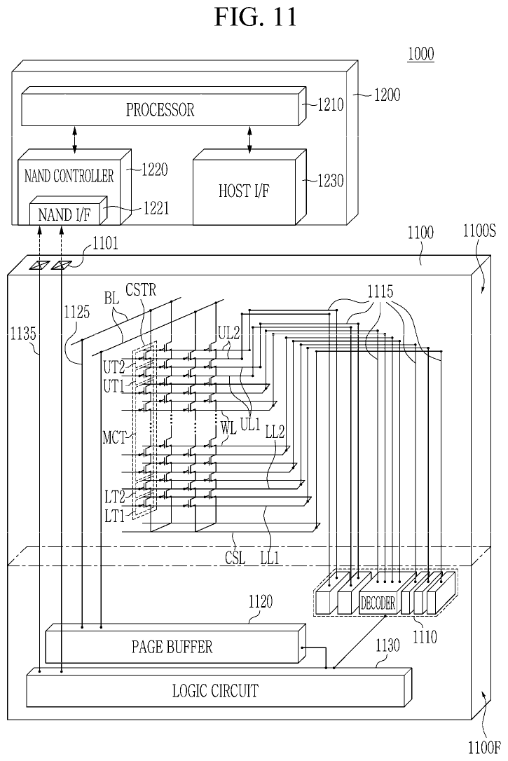

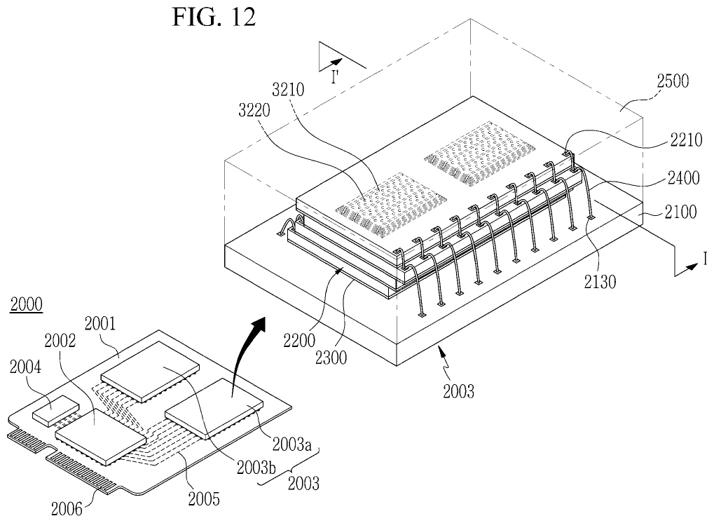

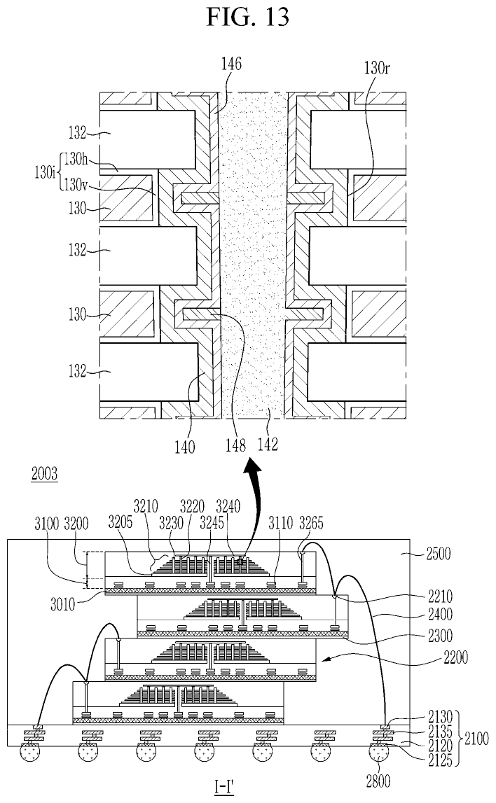

Referring to FIGS. 1 to 3, a semiconductor device 10 according to an embodiment may include a cell area 100 in which a memory cell structure is provided and a circuit area 200 in which a peripheral circuit structure controlling an operation of the memory cell structure is provided. As an example, the circuit area 200 and the cell area 100 may be portions corresponding to a first structure 1100F and a second structure 1100S, respectively, of a semiconductor device 1100 included in an electronic system 1000 illustrated in FIG. 11. Alternatively, the circuit area 200 and the cell area 100 may be portions including a first structure 3100 and a second structure 3200, respectively, of a semiconductor chip 2200 illustrated in FIG. 13.

Here, the peripheral circuit structure formed on a first substrate 210 may be included in the circuit area 200, and a gate stack structure 120 and a channel structure CH formed in a cell array area 102 on a second substrate 110 may be included as the memory cell structure in the cell area 100. A first wiring unit 230 electrically connected to the peripheral circuit structure may be provided in the circuit area 200, and a second wiring unit 180 electrically connected to the memory cell structure may be provided in the cell area 100.

In an embodiment, the cell area 100 may be positioned on the circuit area 200. By doing so, an area corresponding to the circuit area 200 is not provided separately from the cell area 100, and accordingly, it is possible to reduce an area of the semiconductor device 10. However, the embodiment is not limited thereto, and the circuit area 200 may be positioned next to the cell area 100. In addition, modifications may be made in various manners.

The circuit area 200 may include a first substrate 210, circuit elements 220 formed on the first substrate 210, and a first wiring unit 230.

The first substrate 210 may be a semiconductor substrate including a semiconductor material. For example, the first substrate 210 may be a semiconductor substrate made of a semiconductor material, or may be a semiconductor substrate in which a semiconductor layer is formed on a base substrate. As an example, the first substrate 210 may include monocrystalline or polycrystalline silicon, epitaxial silicon, germanium, silicon-germanium, silicon-on-insulator (SOI), germanium-on-insulator (GOI), or the like.

The circuit elements 220 formed on the first substrate 210 may include any of various circuit elements for controlling operations of the memory cell structure provided in the cell area 100. As an example, the circuit elements 220 may constitute the peripheral circuit structure such as a decoder circuit (reference label 1110 in FIG. 11), a page buffer (reference label 1120 in FIG. 11), and/or a logic circuit (reference label 1130 in FIG. 11). The circuit elements 220 may include, for example, transistors, but are not limited thereto. For example, the peripheral circuit elements 220 may include not only active elements such as transistors, but also passive elements such as capacitors, resistors, and inductors.

The first wiring unit 230 positioned on the first substrate 210 may be electrically connected to the circuit elements 220. In an embodiment, the first wiring unit 230 may include a plurality of wiring layers 236 spaced apart from each other with a first insulating layer 232 interposed therebetween and connected to each other by contact vias 234 to form a desired path. The wiring layers 236 or the contact vias 234 may include any of various conductive materials, and the first insulating layer 232 may include any of various insulating materials.

The cell area 100 may include a cell array area 102 and a connection area 104. A gate stack structure 120 and a channel structure CH may be formed on the second substrate 110 in the cell array area 102. A structure for connecting the gate stack structure 120 and/or the channel structure CH formed in the cell array area 102 to the circuit area 200 or an external circuit may be positioned in the connection area 104.

In an embodiment, the second substrate 110 may be a semiconductor substrate including a semiconductor material. For example, the second substrate 110 may be a semiconductor substrate made of a semiconductor material, or may be a semiconductor substrate in which a semiconductor layer is formed on a base substrate. As an example, the second substrate 110 may be made of silicon, germanium, silicon-germanium, silicon-on-insulator, germanium-on-insulator, or the like. Here, the semiconductor material included in the second substrate 110 may be doped with p-type or n-type impurities.

For example, the semiconductor material included in the second substrate 110 may be doped with n-type impurities (e.g., phosphorus (P) or arsenic (As)). However, the exemplified embodiment is not limited to the conductive material formed by doping the semiconductor material with impurities.

The gate stack structure 120 and the channel structure CH may be formed in the cell array area 102. The gate stack structure 120 may include cell insulating layers 132 and gate electrodes 130 alternately stacked in a vertical direction (i.e., Z-axis direction) on a first surface (e.g., a front surface or an upper surface) of the second substrate 110. The channel structure CH may include a portion penetrating through the gate stack structure 120 and extending in an intersection direction intersecting the second substrate 110 (e.g., a vertical direction perpendicular to the first surface of the second substrate 110) (a Z-axis direction in the drawing).

In an embodiment, horizontal conductive layers 112 and 114, extending parallel to the first surface of the second substrate 110 (i.e., in an X-axis and/or Y-axis direction), may be provided between the second substrate 110 and the gate stack structure 120 in the cell array area 102. The horizontal conductive layers 112 and 114 may serve to electrically connect the channel structure CH and the second substrate 110 to each other. As an example, the horizontal conductive layers 112 and 114 may include a first horizontal conductive layer 112 positioned on the first surface of the second substrate 110, and may further include a second horizontal conductive layer 114 positioned on the first horizontal conductive layer 112. A horizontal insulating layer 116, not the first horizontal conductive layer 112, may be provided between the second substrate 110 and the gate stack structure 120 in a partial area of the connection area 104. In the manufacturing process, a partial portion of the horizontal insulating layer 116 may be replaced with the first horizontal conductive layer 112, and the other partial portion of the horizontal insulating layer 116 located in the connection area 104 may remain in the connection area 104.

The first horizontal conductive layer 112 may function as a partial portion of a common source line of the semiconductor device 10. For example, the first horizontal conductive layer 112 may function as a common source line together with the second substrate 110. As illustrated in the enlarged view of FIG. 2, the channel structure CH extends vertically through the gate structure 120 to reach the second substrate 110 by penetrating through the horizontal conductive layers 112 and 114, and the first horizontal conductive layer 112 may be directly connected to a channel layer 140 at a portion where the first horizontal conductive layer 112 is positioned.

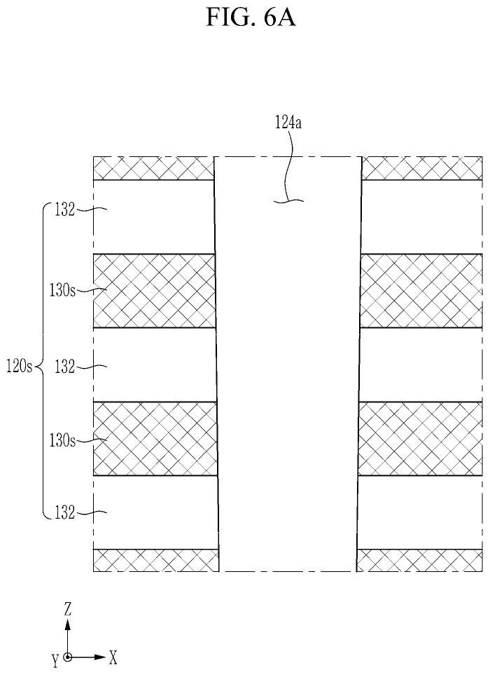

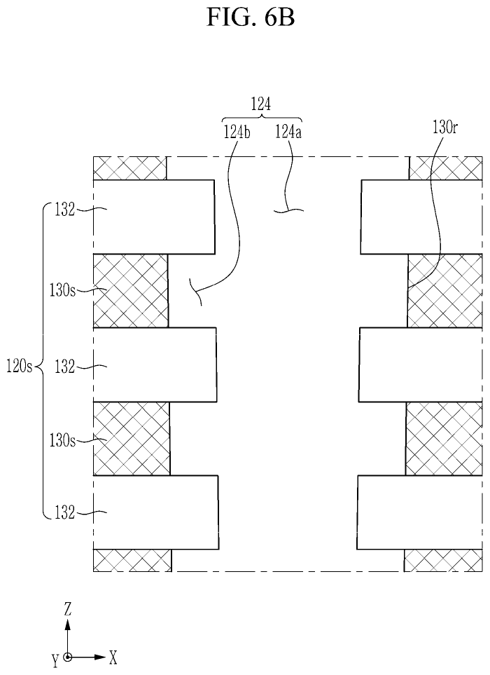

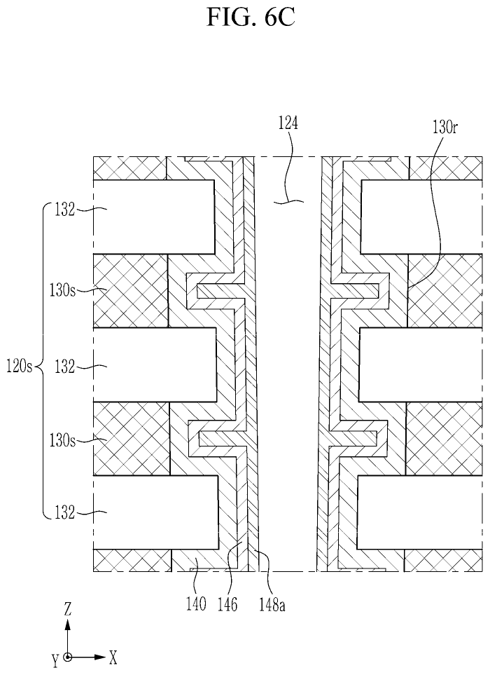

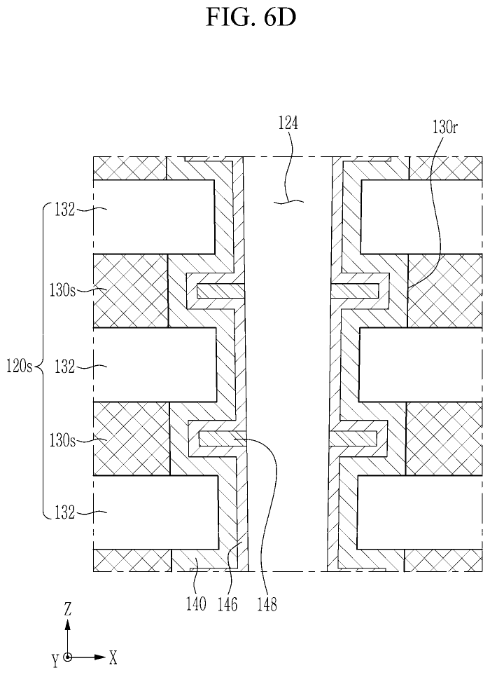

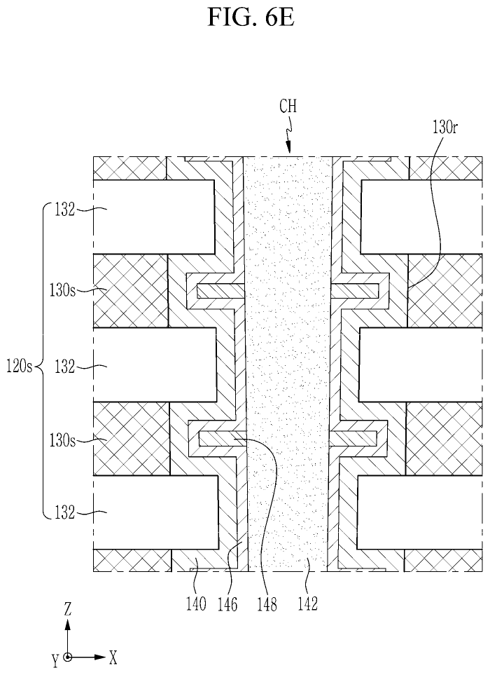

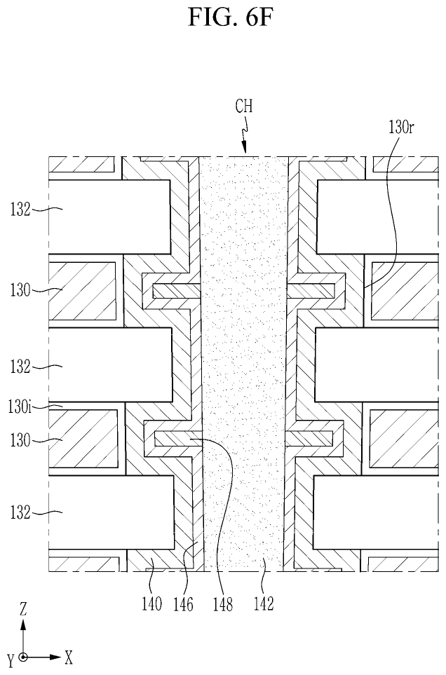

FIG. 2 illustrates an example in which gate insulating layer 130i is positioned on the side where the gate electrodes 130 are formed, and is not positioned on the side where the channel structure CH placed in a through portion (reference sign 124 in FIG. 6A, hereinafter denoted by the same reference sign) is formed. In contrast, in a case where the gate insulating layer 130i is formed before the channel layer 140 of the channel structure CH is formed in the through portion 124, the first horizontal conductive layer 112 may be directly connected to the channel layer 140 on a perimeter of the channel layer 140 by removing a gate insulating layer 130i at a portion where the first horizontal conductive layer 112 is positioned.

The first and second horizontal conductive layers 112 and 114 may include a semiconductor material (e.g., polycrystalline silicon). For example, the first horizontal conductive layer 112 may be a polycrystalline silicon layer doped with impurities or dopants, and the second horizontal conductive layer 114 may be a polycrystalline silicon layer doped with impurities or dopants or a layer including impurities or dopants diffused from the first horizontal conductive layer 112. However, the embodiment is not limited thereto, and the second horizontal conductive layer 114 may be made of an insulating material. Alternatively, the second horizontal conductive layer 114 may not be provided separately.

The gate stack structure 120, in which the plurality of cell insulating layers 132 and the plurality of gate electrodes 130 are alternately stacked, may be positioned on the second substrate 110 (as an example, on the first and second horizontal conductive layers 112 and 114 formed on the second substrate 110).

In the gate stack structure 120, the gate electrodes 130 may include a lower gate electrode, a memory cell gate electrode, and an upper gate electrode sequentially positioned on the second substrate 110. The lower gate electrode may be used as a gate electrode of a ground select transistor, the memory cell gate electrode may constitute a memory cell, and an upper gate electrode may be used as a gate electrode of a string select transistor. The number of memory cell gate electrodes may be determined according to the data storage capacity of the semiconductor device 10. In certain embodiments, one or more lower gate electrodes and one or more upper gate electrodes may be provided, and may have the same structure as the memory cell gate electrode or a different structure from the memory cell gate electrode. Some of the gate electrodes 130, e.g., memory cell gate electrodes adjacent to the lower gate electrode and the upper gate electrode, may be dummy gate electrodes.

The cell insulating layers 132 may include interlayer insulating layers 132m each positioned under the gate electrode 130 or between two adjacent gate electrodes 130 in the gate stack structure 120, and upper insulating layers 132a and 132b positioned at upper portions of the respective gate stack structures 120 (e.g., 120a and 120b). In the embodiment, the plurality of cell insulating layers 132 may not all have the same cross-sectional thickness. For example, the upper insulating layers 132a and 132b may have a greater cross-sectional thickness than the interlayer insulating layers 132m. For simplicity of illustration, it is illustrated in the drawings that one cell insulating layer 132 is provided without a boundary in the connection area 104. However, the cell insulating layer 132 positioned in the connection area 104 may have any of various structures so that either one insulating layer or a plurality of insulating layers may be included, and the embodiment is not limited thereto. In this manner, the shape and structure of the cell insulating layer 132 may be modified in various manners in certain embodiments.

In an embodiment, as illustrated in the enlarged view of FIG. 2 or in FIG. 3, the gate insulating layer 130i made of an insulating material may be positioned on an outer side of the gate electrode 130. For example, the gate insulating layer 130i may include horizontal portions 130h extending horizontally (i.e., in the X-axis and/or Y-axis direction) on upper and lower surfaces of the gate electrode 130, and an extension portion 130v extending in a vertical (i.e., Z-axis) direction, perpendicular to the horizontal portions 130h, on a side surface of the gate electrode 130 adjacent to the channel structure CH.

More specifically, each of the horizontal portions 130h may be positioned between the gate electrode 130 and the cell insulating layer 132. The extension portion 130v may be a portion positioned between the side surface of the gate electrode 130 and the channel layer 140 of the channel structure CH to substantially serve as a gate insulating layer.

The gate insulating layer 130i having the above-described structure may be formed by forming the gate insulating layer 130i before a process of forming the gate electrode 130 in a space for forming the gate electrode 130.

Accordingly, the horizontal portions 130h of the gate insulating layer 130i are not positioned on the side where a recess portion 130r corresponding to the gate electrode 130 is formed. As a result, a recess portion 130r in which a channel layer 140, a resistance change layer 146, etc., are to be positioned has a sufficient space, such that the channel layer 140, the resistance change layer 146, etc., may be stably formed therein.

As described above, in an embodiment, the gate insulating layer 130i may be positioned on the upper surface, the lower surface, and the side surface of the gate electrode 130, respectively. In this case, the gate electrode 130 and the gate insulating layer 130i may be referred to as a gate structure. In the embodiment, a plurality of gate structures including a plurality of gate electrodes 130 and a plurality of cell insulating layers 132 may be alternately stacked in the vertical direction to constitute a gate stack structure 120. In an embodiment, a cross-sectional thickness T (i.e., in a vertical or Z-axis direction) of the gate structure may refer to the sum of cross-sectional thicknesses of the gate electrode 130 and the gate insulating layers 130i positioned on the upper and lower surfaces of the gate electrode 130.

However, the embodiment is not limited thereto, and the gate insulating layer 130i may be formed before the channel layer 140 is formed in the through portion 124 (FIGS. 6A-6D). In this case, the horizontal portions 130h of the gate insulating layer 130i may be provided on lower and upper surfaces of two cell insulating layers 132 constituting the recess portion 130r, respectively, and an extension portion may be positioned therebetween. That is, the gate insulating layers 130i may be formed continuously and entirely between the gate stack structure 120 and the channel layer 140. In this case, a gate structure is constituted by the gate electrode 130, and a thickness T of the gate structure may be a thickness of the gate electrode 130. In addition, modifications may be made in various manners.

The gate electrode 130 may include any of various conductive materials. For example, the gate electrode 130 may include a metal such as tungsten (W), copper (Cu), or aluminum (Al), polycrystalline silicon, or metal nitride (e.g., titanium nitride (TIN), tantalum nitride (TaN), or the like), or a combination thereof. The cell insulating layer 132 may include any of various insulating materials. For example, the cell insulating layer 132 may include silicon oxide, silicon nitride, silicon nitride oxide, a low dielectric constant material having a lower dielectric constant than silicon oxide, or a combination thereof. The gate insulating layer 130i may include an insulating material such as silicon oxide, silicon nitride oxide, or aluminum oxide. The materials of the gate electrode 130, the gate insulating layer 130i, and the cell insulating layer 132 may be modified in various manners, and the embodiment is not limited to what has been described above.

In an embodiment, the channel structure CH may include a portion penetrating through the gate stack structure 120 and extending in the vertical direction intersecting the second substrate 110 (e.g., a vertical direction perpendicular to the first surface of the second substrate 110) (a Z-axis direction in the drawings), and may include a channel layer 140, a resistance change layer 146, and a metal-containing layer 148 sequentially stacked. The channel structure CH may further include a core insulating layer 142 positioned inside of a region defined by the channel layer 140, the resistance change layer 146, and the metal-containing layer 148 (for example, in a central area). The resistance change layer 146 may be referred as a resistance variable layer. In addition, the channel structure CH may further include a channel pad 144 connected to the channel layer 140 in an upper portion of the channel structure CH.

Each of the channel structures CH constitutes one memory cell string, and the plurality of channel structures CHs may be spaced apart from each other while forming rows and columns in a plan view. For example, the plurality of channel structures CHs may be arranged in any of various forms such as a lattice form and a zigzag form in a plan view. The channel structure CH may have a pillar shape. As an example, when viewed in a cross-sectional view, the channel structure CH may have an inclined side surface such that the channel structure CH has a lateral width (i.e., in a horizontal direction parallel to the first surface of the second substrate 110) that becomes narrower as the channel structure CH extends in a direction closer to the second substrate 110 according to an aspect ratio. However, the embodiment is not limited thereto, and the arrangement, structure, and shape of the channel structures CH may be modified in various manners.

In an embodiment, the channel layer 140 may include any of various semiconductor materials. For example, the channel layer 140 may include at least one of a single semiconductor material, an oxide semiconductor material, and a two-dimensional semiconductor material. In a case where the channel layer 140 is made of a single semiconductor material, the channel layer 140 may be formed through an easier process. In a case where the channel layer 140 is made of an oxide semiconductor or a two-dimensional semiconductor material, an operating voltage of the memory cell may be reduced with low resistance. For example, the single semiconductor material may be polycrystalline silicon or the like. The oxide semiconductor material may include indium gallium zinc oxide (IGZO), indium gallium silicon oxide (IGSO), indium tin zinc oxide (ITZO), indium gallium tin oxide (IGTO), indium zinc oxide (IZO), zinc oxide (ZnO), zinc tin oxide (ZTO), zinc oxynitride (ZnON), zirconium zinc tin oxide (ZZTO), tin oxide (SnO), hafnium indium zinc oxide (HIZO), gallium zinc tin oxide (GZTO), aluminum zinc tin oxide (AZTO), ytterbium gallium zinc oxide (YGZO), indium gallium oxide InₓGa_{y}O (IGO), or a combination thereof. The two-dimensional semiconductor material may include graphene, tungsten selenide (WSe₂), or the like. However, the embodiment is not limited thereto, and the material of the channel layer 140 may be modified in various manners.

The resistance change layer 146 may include a transition metal oxide (TMO) of which the internal resistance changes depending on a direction and/or a strength of an electric field applied to the resistance change layer 146 or a voltage applied to the resistance change layer 146. That is, the resistance change layer 146 may be made of a metal oxide including a first metal and oxygen. For example, the first metal may be selected from among zirconium (Zr), hafnium (Hf), aluminum (Al), nickel (Ni), copper (Cu), molybdenum (Mo), tantalum (Ta), titanium (Ti), tungsten (W), chromium (Cr), strontium (Sr), lanthanum (La), manganese (Mn), calcium (Ca), praseodymium (Pr), or a combination thereof.

The metal-containing layer 148 may include a second metal or a metal compound including the second metal. More specifically, the metal-containing layer 148 may include a metal layer including the second metal or a metal nitride layer including the second metal. In a case where the metal-containing layer 148 includes a metal layer or a metal nitride layer, the metal-containing layer 148 may be electrically conductive so that a current flow is not impeded.

The metal-containing layer 148 may be an oxygen-vacancy donor layer that receives oxygen from the resistance change layer 146 and provides oxygen vacancies to the resistance change layer 146 to control oxygen vacancies in the resistance change layer 146. In addition, the thickness of the resistance change layer 146 may be adjusted by changing the thickness of the metal-containing layer 148. The oxygen vacancies and the thickness of the resistance change layer 146 are factors that have the greatest influences on cell properties of the memory cells. In the embodiment, the oxygen vacancies and the thickness of the resistance change layer 146 may be easily adjusted using the metal-containing layer 148.

In order to receive oxygen from the resistance change layer 146 and provide oxygen vacancies to the resistance change layer 146, a Gibbs free energy of oxidation reaction of the second metal included in the metal-containing layer 148 may be equal to or smaller than a Gibbs free energy of oxidation reaction of the first metal included in the resistance change layer 146. The Gibbs free energy is an important thermodynamic function for characterizing a system, and is a factor in determining outcomes such as the voltage of an electrochemical cell, and the equilibrium constant for a reversible reaction. This may mean that the second metal may be oxidized or form an oxide by reacting with oxygen at the same level as the first metal or better than the first metal. In this state, oxygen in the resistance change layer 146 may move to the metal-containing layer 148. As an example, the Gibbs free energy of the oxidation reaction of the second metal may be negative. Then, the spontaneous oxidation reaction of the second metal may occur. For example, in a case where both the Gibbs free energy of the oxidation reaction of the first metal and the Gibbs free energy of the oxidation reaction of the second metal are negative, an absolute value of the Gibbs free energy of the oxidation reaction of the second metal may be greater than an absolute value of the Gibbs free energy of the oxidation reaction of the first metal. However, the embodiment is not limited thereto, and the Gibbs free energy of the oxidation reaction of the second metal may be 0 or positive. In addition, the metal-containing layer 148 may not include oxygen, or may include oxygen in a lower content than the resistance change layer 146. This is because oxygen in the resistance change layer 146 may migrate to the metal-containing layer 148 in this case.

In an embodiment, the metal-containing layer 148 may include at least one of hafnium (Hf), titanium (Ti), zirconium (Zr), lanthanum (La), tantalum (Ta), aluminum (Al), nickel (Ni), tungsten (W), copper (Cu), gold (Au), ruthenium (Ru), platinum (Pt), titanium nitride (TIN), and tantalum nitride (TaN).

For example, the metal-containing layer 148 may include at least one of titanium, tungsten, titanium nitride, and tantalum nitride. This is because these materials can be easily formed through an atomic layer deposition (ALD) process and can be easily etched to have a desired pattern through an etching process. Alternatively, the metal-containing layer 148 may include at least one of hafnium, titanium, zirconium, lanthanum, tantalum, and aluminum. This is because a Gibbs free energy of oxidation reaction is small in these materials, such that oxygen can easily move from the resistance change layer 146 to the metal-containing layer 148.

As an example, the metal-containing layer 148 may include titanium. In this case, at least a partial portion of the metal-containing layer 148 may be formed of a metal layer made of titanium, which is a single metal. This is because titanium is a metal having a small Gibbs free energy of oxidation reaction and enables oxygen to more easily move from the resistance change layer 146 to the metal-containing layer 148 than a metal compound (e.g., metal nitride). In addition, the metal-containing layer 148 including titanium is easy to form and etch, and has a low resistance, thereby making it possible to improve various properties. However, the embodiment is not limited thereto, and the material of the metal-containing layer 148 may be modified in various manners.

In the process of forming the metal-containing layer 148, a metal layer made of the second metal or a metal compound layer (e.g., metal nitride layer) made of a metal compound (e.g., metal nitride) including the second metal may be formed. Such a metal layer or metal compound layer may be made of an oxygen-free layer that does not contain oxygen. In the final structure, the metal-containing layer 148 may be maintained as an oxygen-free layer or may include an oxygen-free layer. Alternatively, oxygen in the resistance change layer 146 or the like may move to the metal-containing layer 148 through various subsequent processes performed after the metal-containing layer 148 is formed. In this manner, the metal-containing layer 148 may include oxygen. Even in this case, however, a ratio of an oxygen content of the metal-containing layer 148 to an oxygen content of the resistance change layer 146 may be 10% or less (e.g., 5% or less). This is because the oxygen included in the metal-containing layer 148 has been moved from the resistance change layer 146 and the like. Since the metal-containing layer 148 does not include oxygen or has a relatively low oxygen content as described above, the metal-containing layer 148 may maintain excellent electrical conductivity while not impeding a current flow.

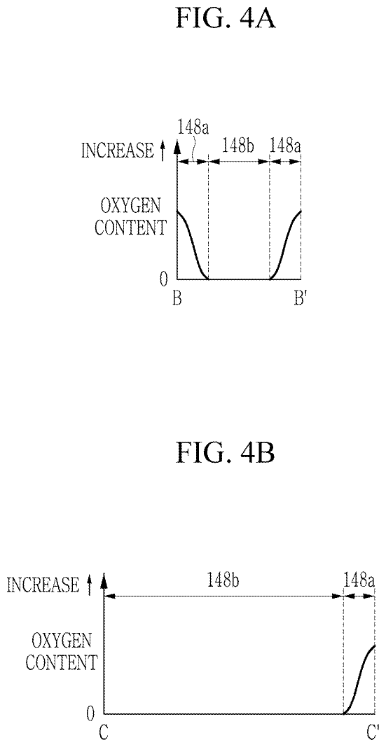

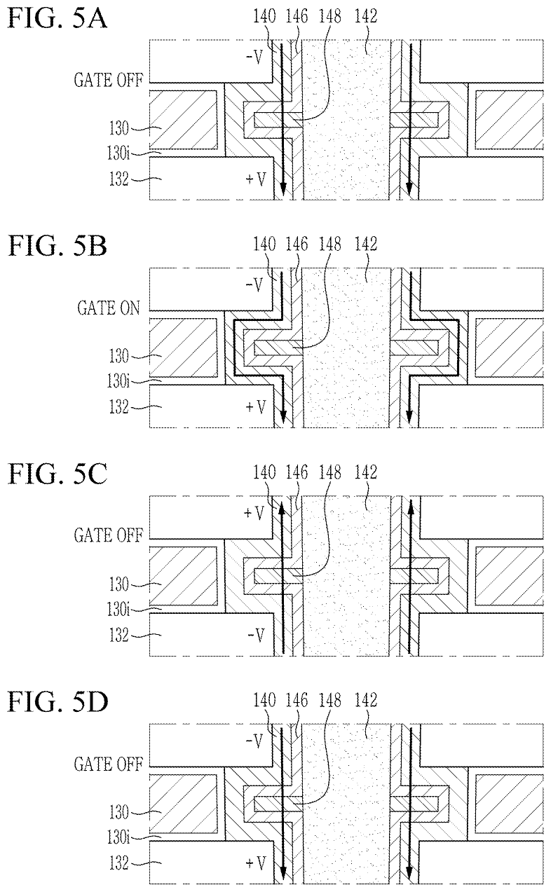

An example of distribution of oxygen included in the metal-containing layer 148 will be described in detail with reference to FIGS. 4A and 4B. FIGS. 4A and 4B are graphs illustrating oxygen contents along line B-B′ and line C-C′, respectively, of FIG. 3.

Referring to FIGS. 4A and 4B, the metal-containing layer 148 may include oxygen at least in a portion adjacent to the resistance change layer 146. For example, the metal-containing layer 148 may include an oxygen-containing layer 148a including oxygen at least in a portion adjacent to the resistance change layer 146. The oxygen-containing layer 148a may be formed in the form of an oxide layer, although embodiments are not limited thereto. For example, the metal-containing layer 148 may partially or entirely include an oxide layer included in the metal-containing layer 148 and including the second metal at an interface with the resistance change layer 146.

In this case, the oxygen-containing layer 148a may be formed of a metal oxide layer in which oxygen is bonded to a metal layer included in the metal-containing layer 148 and including the second metal, or a metal nitride oxide layer in which oxygen is bonded to a metal nitride layer including the second metal. However, the shape or the type of the oxygen-containing layer 148a may be modified in various manners.

In addition, the metal-containing layer 148 or the oxygen-containing layer 148a may have an oxygen content that becomes lower in a direction farther away from the portion adjacent to the resistance change layer 146. For example, the oxygen content distribution in the metal-containing layer 148 or the oxygen-containing layer 148a may have an upwardly convex shape at a portion adjacent to the resistance change layer 146 and a downwardly convex shape at the opposite portion thereof. This may be because oxygen that moved from the resistance change layer 146 was accumulated at the boundary between the resistance change layer 146 and the metal-containing layer 148 and then has moved to the resistance change layer 146. However, the embodiment is not limited thereto. Therefore, the oxygen content of the metal-containing layer 148 or the oxygen-containing layer 148a may linearly decrease in a direction farther away from the resistance change layer 146, or may decrease to have a distribution in an upwardly or downwardly convex shape entirely. The oxygen-containing layer 148a may be checked by any of various methods such as micrographs and component analysis.

In FIG. 4A, it is exemplified that the oxygen-containing layers 148a are provided in upper and lower portions, respectively, of the metal-containing layer 148 adjacent to the resistance change layer 146 in the vertical (i.e., Z-axis) direction, and an oxygen-free layer 148b that does not include oxygen is positioned between the oxygen-containing layers 148a positioned in the upper and lower portions, respectively, of the metal-containing layer 148. In FIG. 4B, it is exemplified that the oxygen-containing layer 148a is provided on one side surface of the metal-containing layer 148 adjacent to the resistance change layer 146 in the horizontal (X-axis and/or Y-axis) direction, and the oxygen-free layer 148b, which does not include oxygen, is positioned on the other side surface of the metal-containing layer 148 located opposite to the resistance change layer 146. Since the oxygen-containing layer 148a is locally positioned in a partial portion of the metal-containing layer 148 as described above, the metal-containing layer 148 may have excellent electrical properties.

However, the embodiment is not limited thereto. The oxygen content may be maintained at a certain level inside the metal-containing layer 148 after gradually decreasing as the metal-containing layer 148 is farther away from the resistance change layer 146 in the horizontal direction. Then, the metal-containing layer 148 may be formed of only the oxygen-containing layer 148a.

From the oxygen distribution described above, it may be inferred that oxygen in the metal-containing layer 148 is caused by movement of the oxygen from the resistance change layer 146. Although it has been described above that the metal-containing layer 148 does not include oxygen in the process of forming the metal-containing layer 148, the embodiment is not limited thereto. In the process of forming the metal-containing layer 148, the metal-containing layer 148 may inevitably include oxygen, or the metal-containing layer 148 may be formed to include oxygen with a lower content than the resistance change layer 146.

Referring back to FIGS. 1 to 3, the core insulating layer 142 may include any of various insulating materials. For example, the core insulating layer 142 may include silicon oxide, silicon nitride, silicon nitride oxide, or a combination thereof. However, the embodiment is not limited to the above-described material of the core insulating layer 142.

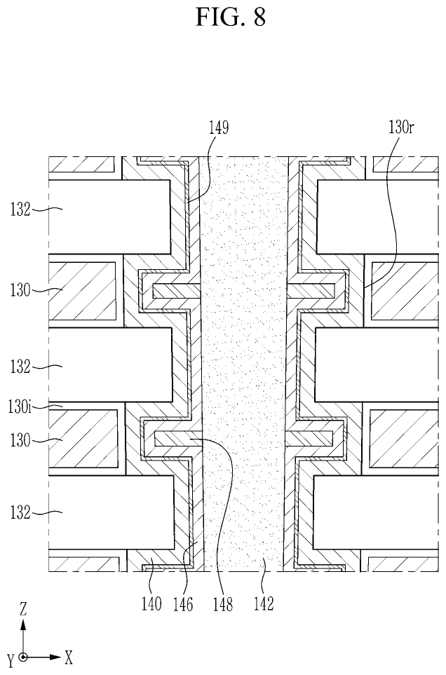

As an example, the resistance change layer 146 may be directly connected to or in contact with the channel layer 140 to simplify the structure. However, the embodiment is not limited thereto, and another example will be described in detail below with reference to FIG. 8. As an example, the metal-containing layer 148 may be directly connected to or in contact with the resistance change layer 146, such that the metal-containing layer 148 effectively controls oxygen vacancies in the resistance change layer 146. However, the embodiment is not limited thereto, and another layer may be positioned between the resistance change layer 146 and the metal-containing layer 148. As an example, the metal-containing layer 148 and the resistance change layer 146 may be directly connected to or in contact with the core insulating layer 142 to simplify the structure. However, the embodiment is not limited thereto, and a separate layer may be positioned between the metal-containing layer 148 and the resistance change layer 146 and the core insulating layer 142.

In an embodiment, the channel structure CH may include a portion in which a channel layer 140, a resistance change layer 146, a metal-containing layer 148, a resistance change layer 146, and a channel layer 140 are sequentially positioned in the vertical (i.e., Z-axis) direction. For example, the gate electrode 130 may include a recess portion 130r. A channel layer 140, a resistance change layer 146, a metal-containing layer 148, a resistance change layer 146, and a channel layer 140 may be sequentially positioned in the vertical direction at a position corresponding to the gate electrode 130 or at a portion where the recess portion 130r is positioned.

Accordingly, a direction of a driving current and a direction of an electric field applied to the resistance change layer 146 coincide with each other within the recess portion 130r. As a result, it is possible to reduce an operating voltage of the memory cell for a program operation, an erase operation, a read operation, or the like. On the other hand, if the recess portion 130r is not provided, since the channel layer 140, the resistance change layer 146, and the metal-containing layer 148 are stacked only in the horizontal direction, the electric field applied to the resistance change layer 146 needs to be bent, and thus, the operating voltage needs to increase. In addition, in the embodiment, the channel layer 140, the resistance change layer 146, and the metal-containing layer 148 may be positioned in the recess portion 130r to prevent the channel layer 140 and the resistance change layer 146 from being damaged in the process for forming the metal-containing layer 148 or in various subsequent processes (e.g., an etching process) performed after the metal-containing layer 148 is formed.

More specifically, the through portion 124 (FIGS. 6A-6B) may be formed in the gate stack structure 120, and the channel structure CH may be formed in the through portion 124. In an embodiment, the through portion 124 may include a penetration portion (reference label 124a in FIG. 6B, hereinafter denoted by the same reference label) and an extension portion 124b extending from the penetration portion 124a toward the gate electrode 130 in the horizontal direction. Accordingly, on the side surface of the gate stack structure 120 adjacent to the channel structure CH, the cell insulating layers 132 may be formed to protrude as compared with the gate electrodes 130 in the horizontal direction, and recess portions 130r may be positioned to correspond to the respective gate electrodes 130. As a result, a plurality of recess portions 130r corresponding to the plurality of gate electrodes 130, respectively, may be positioned on the side surface of the gate stack structure 120 adjacent to the channel structure CH.

The channel layer 140 and the resistance change layer 146 included in the channel structure CH may be formed in such a manner as to extend in the vertical direction and in the horizontal direction repeatedly on the side surface of the gate stack structure 120 including the plurality of recess portions 130r or on the side surface of the through portion 124 inside the through portion 124 continuously and entirely. On the other hand, a plurality of metal-containing layers 148 may be provided to individually correspond to the plurality of recess portions 130r, respectively. The plurality of metal-containing layers 148 corresponding to the plurality of recess portions 130r, respectively, may be spaced apart from each other with the channel layer 140, the resistance change layer 146, the cell insulating layer 132, and the like interposed therebetween. When viewed in a plan view, the metal-containing layer 148 may have an annular shape surrounding (i.e., extending around) the core insulating layer 142. The term “surrounding” (or “surrounds,” or like terms) as may be used herein is intended to broadly refer to an element, structure or layer that envelops, extends around, encircles, or encloses another element, structure or layer on all sides, although breaks or gaps may also be present. Thus, for example, a material layer having voids therein may still “surround” another layer which it encircles. However, the embodiment is not limited thereto.

For example, the channel layer 140 may be formed along an upper surface, a side surface, and a lower surface of the cell insulating layer 132, and the side surface of the gate electrode 130 repeatedly to be formed on the side surface of the through portion 124 continuously and entirely. That is, the channel layer 140 may include a plurality of first channel portions 140a, 140b, and 140c corresponding to each of the plurality of recess portions 130r, and a second channel portion 140d extending in the vertical direction and connecting the plurality of first channel portions 140a, 140b, and 140c on the side surface of the cell insulating layer 132. The first channel portions 140a, 140b, and 140c may include a first horizontal portion 140a positioned in an upper portion of the recess portion 130r and extending in the horizontal direction on the lower surface of the cell insulating layer 132, a second horizontal portion 140b positioned in a lower portion of the recess portion 130r and extending in the horizontal direction on the upper surface of the cell insulating layer 132, and a side portion 140c extending in the vertical direction and connecting the first horizontal portion 140a and the second horizontal portion 140b to each other on the side surface of the gate insulating layer 130i.

Similarly, the resistance change layer 146 may be formed along the upper surface, the side surface, and the lower surface of the cell insulating layer 132, and the side surface of the gate electrode 130 repeatedly on the channel layer 140 to be formed on the side surface of the through portion 124 continuously and entirely. That is, the resistance change layer 146 may include a plurality of first portions 146a, 146b, and 146c formed to correspond to each of the plurality of recess portions 130r on the channel layer 140, and a second portion 146d extending in the vertical direction and connecting the plurality of first portions 146a, 146b, and 146c on the channel layer 140 positioned on the side surface of the cell insulating layer 132. The first portions 146a, 146b, and 146c may include a first horizontal portion 146a positioned in the upper portion of the recess portion 130r and extending in the horizontal direction on a lower surface of the first horizontal portion 140a of the channel layer 140, a second horizontal portion 146b positioned in the lower portion of the recess portion 130r and extending in the horizontal direction on an upper surface of the second horizontal portion 140b of the channel layer 140, and a side portion 146c extending in the vertical direction and connecting the first horizontal portion 146a and the second horizontal portion 146b to each other on the channel layer 140 positioned on the side surface of the gate insulating layer 130i.

The metal-containing layer 148 may be partially formed on the resistance change layer 146 to individually correspond to each of the recess portions 130r (for example, to correspond in a one-to-one manner). For example, the metal-containing layer 148 positioned in the recess portion 130r may be formed on the side surface of the resistance change layer 146 (more specifically, the side portion 146c) in the horizontal direction to fill a space between the resistance change layers 146 (more specifically, between the first horizontal portion 146a of the resistance change layer 146 and the second horizontal portion 146b of the resistance change layer 146) in the vertical direction.

For example, when viewed in the intersection direction, the resistance change layers 146 may be positioned on (for example, in contact with) both sides of one metal-containing layer 148, respectively. That is, by inserting each metal-containing layer 148 between the first horizontal portion 146a and the second horizontal portion 146b of the resistance change layer 146 in contact with the first horizontal portion 146a and the second horizontal portion 146b of the resistance change layer 146, it is possible to effectively control oxygen vacancies in the resistance change layers 146 positioned on both sides with a simple structure.

In addition, when viewed in the horizontal direction, one side surface of the metal-containing layer 148 positioned close to the gate electrode 130 may contact the side surface of the resistance change layer 146, and the other side surface of the metal-containing layer 148 and the other side surface of the resistance change layer 146 opposite to the side surface of the gate stack structure 120 adjacent to the channel structure CH may be positioned on the same plane. The metal-containing layer 148 formed individually in each recess portion 130r may be easily formed through a process of removing the metal-containing layer 148 formed on the resistance change layer 146 at a portion where the cell insulating layer 132 is positioned. However, the embodiment is not limited thereto, and the other side surface of the metal-containing layer 148 and the other side surface of the resistance change layer 146 may be positioned on different planes.

In this manner, the metal-containing layer 148 is individually formed to correspond to each recess portion 130r, and the metal-containing layer 148 is not entirely formed in a direction in which the channel structure CH extends. Accordingly, while serving to adjust oxygen vacancies in the resistance change layer 146, the metal-containing layer 148 is capable of preventing an undesired change of a current path. As a result, the metal-containing layer 148 has a structure suitable for being included in the channel structure CH including a portion extending in the intersection direction. On the other hand, unlike the embodiment, in a case where the metal-containing layer is formed entirely and continuously like the channel layer 140 and the resistance change layer 146, a current flows into the metal-containing layer, a current path may change, and a short circuit may be caused.

In the embodiment, a cross-sectional thickness of the recess portion 130r in the intersection direction may be substantially equal to a thickness T of the gate structure. Here, as described above, the thickness of the gate structure may refer to the sum of the cross-sectional thickness of the gate electrode 130 and the cross-sectional thicknesses of the gate insulating layers 130i positioned on the upper and lower surfaces thereof. In the present specification, the thickness may refer to a thickness in the vertical direction (e.g., a direction perpendicular to the first surface of the second substrate 110) (a Z-axis direction in the drawing). In this case, the thickness T of the gate structure may be substantially equal to the sum of cross-sectional thicknesses of the channel layer 140, the resistance change layer 146, and/or the metal-containing layer 148 positioned inside the recess portion 130r.

However, the embodiment is not limited thereto. For example, in an etching process for forming the recess portion 130r, an upper portion and/or a lower portion of a sacrificial insulating layer (see reference label 130s in FIG. 6B) for forming the gate structure may be etched together. In this case, the thickness of the recess portion 130r may be greater than the thickness of the gate structure, and the sum of thicknesses of the channel layer 140, the resistance change layer 146, and/or the metal-containing layer 148 positioned inside the recess portion 130r may be greater than the thickness T of the gate structure. In addition, modifications may be made in various manners.

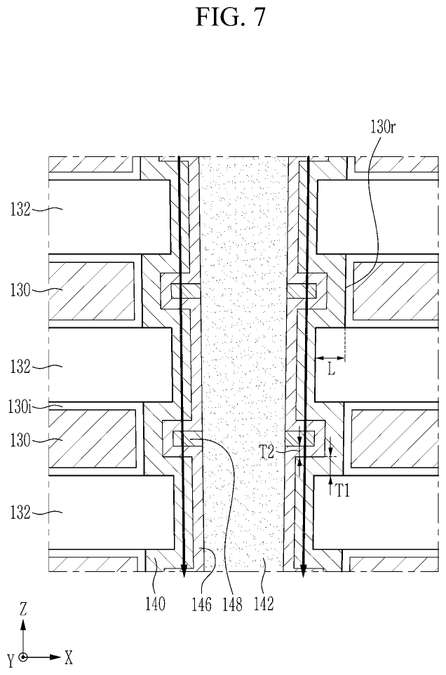

In an embodiment, a width L of the recess portion 130r in the horizontal direction may be greater than the sum of a thickness T1 of the channel layer 140 and a thickness T2 of the resistance change layer 146. By making the width L (in the X-axis direction) of the recess portion 130r greater than the sum of the cross-sectional thickness T1 of the channel layer 140 and the cross-sectional thickness T2 of the resistance change layer 146, the channel layer 140, the resistance change layer 146, and/or the metal-containing layer 148 can be stably positioned in the recess portion 130r. However, the embodiment is not limited thereto. In the embodiment, the width L of the recess portion 130r in the horizontal direction may be substantially equal to the sum of the cross-sectional thickness of the channel layer 140 and the cross-sectional thickness of the resistance change layer 146. This will be described in more detail with reference to FIG. 7 below.

As an example, the width L of the recess portion 130r may be equal to or smaller than the thickness T of the gate structure or the cross-sectional thickness of the recess portion 130r. Accordingly, the distribution of the operating voltage of the memory cell can be reduced. As another example, the width L of the recess portion 130r may be greater than the thickness T of the gate structure or the cross-sectional thickness of the recess portion 130r. Then, the channel layer 140, the resistance change layer 146, and the metal-containing layer 148 may be more stably positioned in the recess portion 130r.

In an embodiment, the cross-sectional thicknesses of the resistance change layer 146 and the metal-containing layer 148 may be variously adjusted to implement desired properties in the semiconductor device 10.

As an example, a cross-sectional thickness T3 of the metal-containing layer 148 may be equal to or greater than the thickness T2 of the resistance change layer 146. This is because, when viewed from the perspective of each recess portion 130r, the resistance change layer 146 is provided as two layers in the vertical direction, and the metal-containing layer 148 is provided as one layer between the two resistance change layers 146. Accordingly, the metal-containing layer 148 can sufficiently provide oxygen vacancies to the resistance change layer 146, thereby lowering the resistance and the operating voltage. As another example, the thickness T3 of the metal-containing layer 148 may be smaller than the thickness T2 of the resistance change layer 146. Accordingly, retention can be improved even though the metal-containing layer 148 is included, and endurance can be improved by reducing leakage current.

Alternatively, the thickness T3 of the metal-containing layer 148 may be about 2 nm to 10 nm (e.g., 3 nm to 5 nm), and the thickness T2 of the resistance change layer 146 may be about 1 nm to 5 nm (e.g., 2 nm to 3 nm). If the thickness T3 of the metal-containing layer 148 is smaller than 2 nm, the effect of the metal-containing layer 148 for controlling oxygen vacancies in the resistance change layer 146 may not be sufficient. If the thickness T3 of the metal-containing layer 148 is greater than 10 nm, there may be a limit in reducing the thickness of the gate electrode 130. In addition, if the thickness T2 of the resistance change layer 146 is smaller than 1 nm, the resistance of the resistance change layer 146 may increase and thus the operating voltage may increase. If the thickness T2 of the resistance change layer 146 is greater than 5 nm, there may be a limit in reducing the thickness of the gate electrode 130. Considering the effects of the metal-containing layer 148 and the resistance change layer 146 together with the cross-sectional thickness of the gate electrode 130, the cross-sectional thickness of the metal-containing layer 148 may be 3 nm to 5 nm, and the thickness of the resistance change layer 146 may be 2 nm to 3 nm, in some embodiments.

The thickness T1 of the channel layer 140 may be formed to a sufficient thickness to satisfy resistance properties. For example, in a case where the channel layer 140 is made of a single semiconductor material, the thickness T1 of the channel layer 140 may be equal to or greater than the thickness T2 of the resistance change layer 146 or the thickness T3 of the metal-containing layer 148. Accordingly, the resistance of the channel layer 140 can be lowered to a certain level or less. However, the embodiment is not limited thereto, and in a case where the channel layer 140 is made of a single semiconductor material, the thickness T1 of the channel layer 140 may be smaller than the thickness T2 of the resistance change layer 146 or the thickness T3 of the metal-containing layer 148. As another example, in a case where the channel layer 140 is made of a two-dimensional semiconductor material, an oxide semiconductor material, or the like, the thickness T1 of the channel layer 140 may be equal to or smaller than the thickness T3 of the metal-containing layer 148 or the thickness T2 of the resistance change layer 146. This is because the two-dimensional semiconductor material, the oxide semiconductor material, or the like has excellent electrical properties, and thus, the channel layer 140 can have a resistance at a certain level or less even though the channel layer 140 has a small thickness. However, the embodiment is not limited thereto, and in a case where the channel layer 140 is made of a two-dimensional semiconductor material, an oxide semiconductor material, or the like, the thickness T1 of the channel layer 140 may be greater than the thickness T3 of the metal-containing layer 148 or the thickness T2 of the resistance change layer 146.

The above-described thicknesses of the channel layer 140, the resistance change layer 146, and the metal-containing layer 148 are merely presented as an example, and the embodiment is not limited thereto. Therefore, the thicknesses of the metal-containing layer 148, the resistance change layer 146, and the channel layer 140 may be variously changed.

The channel pad 144 connected to the channel layer 140 may be positioned in the upper portion of the channel structure CH. For example, the channel pad 144 may be disposed to be connected to the channel layer 140 while being positioned in an upper portion of the core insulating layer 142. The resistance change layer 146 may be removed at a portion where the channel pad 144 is positioned, so that a side surface of the channel layer 140 is directly connected to a side surface of the channel pad 144. Since the resistance change layer 146 has a high resistance because it is made of a transition metal oxide, the resistance change layer 146 is removed so that the channel layer 140 and the channel pad 144 are in direct contact with each other in a face-to-face structure to improve electrical properties. The channel pad 144 may include a conductive material, e.g., polycrystalline silicon doped with impurities, but is not limited thereto.

In an embodiment, the gate stack structure 120 may include a plurality of gate stack structures 120a and 120b sequentially stacked on the second substrate 110, and the channel structure CH may include a plurality of channel structures CH1 and CH2 extending vertically (i.e., in the Z-axis direction) and penetrating through the plurality of gate stack structures 120a and 120b. Then, it is possible to increase the number of stacked gate electrodes 130, and accordingly, it is possible to increase the number of memory cells in a stable structure. In the drawings, it is exemplified that two gate stack structures 120 are provided, but the embodiment is not limited thereto. For example, the gate stack structure 120 may be formed as one gate stack structure, or, in other embodiments, may include three or more gate stack structures.

The plurality of channel structures CH1 and CH2 constituting one channel structure CH may be connected to each other. When viewed in a cross-sectional view, each of the plurality of channel structures CH1 and CH2 may have an inclined side surface to have a width that becomes narrower in a direction closer to the second substrate 110 according to an aspect ratio. Accordingly, the extension portion 130v of the gate insulating layer 130i, the side portion 140c of the channel layer 140, the side portion 146c of the resistance change layer 146, and one side surface and the other side surface of the metal-containing layer 148 may be inclined. In addition, as illustrated in FIG. 2, a bent portion may be provided due to a difference in width between the first channel structure CH1 and the second channel structure CH2 at a portion where they are connected to each other. As another example, the plurality of channel structures CH1 and CH2 may have inclined side surfaces continuously connected to each other without a bent portion.

In FIG. 2, it is exemplified that the channel layers 140, the resistance change layers 146, and the core insulating layers 142 of the plurality of channel structures CH1 and CH2 have an integral structure formed by extending with respect to each other. However, the embodiment is not limited thereto, and the channel layers 140, the resistance change layers 146, and the core insulating layers 142 of the plurality of channel structures CH1 and CH2 may be separately formed from each other and electrically connected to each other. Also, a separate channel pad may be additionally provided at a portion where the plurality of channel structures CH1 and CH2 are connected to each other. The embodiment is not limited to the above-described form of the plurality of channel structures CH1 and CH2 described above.

In an embodiment, the gate stack structure 120 may be divided into a plurality of gate stack structures in a plane view by an isolation structure 160 extending in the vertical direction (e.g., a direction perpendicular to the first surface of the second substrate 110) (a Z-axis direction in the drawings) intersecting (i.e., perpendicular to) the second substrate 110 and penetrating vertically through the gate stack structure 120. In addition, an upper isolation region 162 may be formed in an upper portion of the gate stack structure 120. In a plan view, a plurality of isolation structures 160 and/or a plurality of upper isolation regions 162 may be provided to extend in a first direction (a Y-axis direction in the drawings) while being spaced apart from each other at a predetermined interval in a second direction (an X-axis direction in the drawings) intersecting the first direction.

By the isolation structures 160, the plurality of gate stack structures 120 may be spaced apart from each other in the second direction (the X-axis direction in the drawings) in a plan view, while each extending in the first direction (the Y-axis direction in the drawings). The gate stack structure 120 divided by the isolation structures 160 may constitute one memory cell block. However, the embodiment is not limited thereto, and the range of the memory cell block is not limited thereto.

For example, the isolation structures 160 may penetrate through the gate stack structure 120 and extend vertically to the second substrate 110, and the upper isolation region 162 may isolate one of the plurality of gate electrodes 130 or isolate some of the plurality of gate electrodes 130 from each other. The upper isolation region 162 may be positioned between the isolation structures 160.

As an example, it has been exemplified that, when viewed in a cross-sectional view, the isolation structure 160 has an inclined side surface to have a width that gradually decreases toward the second substrate 110 due to a high aspect ratio, but the embodiment is not limited thereto. A side surface of the isolation structure 160 may be perpendicular to the second substrate 110 or may have a bent portion at a portion where the plurality of gate stack structures 120a and 120b are connected to each other.

The isolation structure 160 or the upper isolation region 162 may be filled with any of various insulating materials. The term “filled” (or “filling,” “fill,” or like terms) as may be used herein is intended to refer broadly to either completely filling a defined space (e.g., isolation structure 160 or the upper isolation region 162) or partially filling the defined space; that is, the defined space need not be entirely filled but may, for example, be partially filled or have voids or other spaces throughout. For example, the isolation structure 160 or the upper isolation region 162 may include an insulating material such as silicon oxide, silicon nitride, or silicon nitride oxide. However, the embodiment is not limited thereto, and the structure, the shape, and the material of the isolation structure 160 or the upper isolation region 162 may be variously modified.

The connection area 104 and the second wiring unit 180 may be provided to connect the gate stack structure 120 and the channel structure CH provided in the cell array area 102 to the circuit area 200 or an external circuit. The connection area 104 may be disposed around the cell array area 102, and a part portion of the second wiring unit 180 may be positioned in the connection area 104.

Here, the second wiring unit 180 may include all members electrically connecting the gate electrodes 130, the channel structure CH, the horizontal conductive layers 112 and 114, and/or the second substrate 110 to the circuit area 200 or an external circuit. For example, the second wiring unit 180 may include a bit line 182, a gate contact unit 184, a source contact unit 186, a through plug 188, a contact via 180a connected to each of them, and a connection wire 190 connecting them to each other.

The bit line 182 may be positioned above the cell insulating layer 132 of the gate stack structure 120 formed in the cell array area 102. The bit line 182 may extend in the second direction (the X-axis direction in the drawings) intersecting the first direction in which the gate electrode 130 extends. The bit line 182 may be electrically connected to the channel structure CH, e.g., the channel pad 144, through the contact via 180a, e.g., a bit line contact via.

A plurality of gate electrodes 130 may be positioned to extend in the first direction (the Y-axis direction in the drawings) in the connection area 104, and the extension lengths of the plurality of gate electrodes 130 in the connection area 104 may sequentially decrease in a direction farther away from the second substrate 110. For example, the plurality of gate electrodes 130 may be positioned in a stepped shape in the connection area 104. In this case, the plurality of gate electrodes 130 may have a stepped shape in one direction or in a plurality of directions. In the connection area 104, a plurality of gate contact units 184 may be electrically connected to the plurality of gate electrodes 130 extending to the connection area 104, respectively, by penetrating through the cell insulating layers 132.

In the drawing, it is exemplified that the gate contact unit 184 is positioned to connect an upper side of the gate electrode 130 and the connection wire 190 to each other. However, the embodiment is not limited thereto. As another example, the gate contact unit 184 may penetrate through the gate electrode 130 and extend to the circuit area 200 to be electrically connected to the circuit area 200. In addition, other modifications may be made.

In the connection area 104, the source contact unit 186 may penetrate vertically (i.e., in the Z-axis direction) through the cell insulating layer 132 to be electrically connected to the horizontal conductive layers 112 and 114 and/or the second substrate 110, and the through plug 188 may penetrate vertically (i.e., in the Z-axis direction) through the gate stack structure 120 or be disposed outside the gate stack structure 120 to be electrically connected to the first wiring unit 230 in the circuit area 200.

The connection wire 190 may be positioned in the cell array area 102 and/or the connection area 104. The bit line 182, the gate contact unit 184, the source contact unit 186, and/or the through plug 188 may be electrically connected to the connection wire 190. For example, the gate contact unit 184, the source contact unit 186, and/or the through plug 188 may be connected to the connection wire 190 through the contact via 180a.

In FIG. 1, it is exemplified that the connection wire 190 is provided as a single layer positioned on the same plane as the bit line 182, and a second insulating layer 192 is positioned in a portion other than the second wiring unit 180. However, this is merely a brief illustration for convenience. The connection wire 190 may include a plurality of wiring layers and may further include contact vias for electrical connection with the bit line 182, the gate contact unit 184, the source contact unit 186, and/or the through plug 188.

As described above, the bit line 182, the gate electrode 130, the horizontal conductive layers 112 and 114, and/or the second substrate 110 connected to the channel structure CH may be electrically connected to the circuit elements 220 of the circuit area 200 by the second wiring unit 180 and the first wiring unit 230.

In FIG. 1, it is exemplified that, when viewed in a cross-sectional view, the gate contact unit 184, the source contact unit 186, and/or the through plug 188 may have an inclined side surface to have a width (in the X-axis direction) that becomes narrower in a direction closer to the second substrate 110 according to an aspect ratio, and a bent portion may be provided at a boundary between the plurality of gate stack structures 120a and 120b. However, the embodiment is not limited thereto. The gate contact unit 184, the source contact unit 186, and/or the through plug 188 may not have a bent portion at the boundary between the plurality of gate stack structures 120a and 120b. In addition, modifications may be made in various manners.

In the above-described embodiment, one gate electrode 130, the gate insulating layer 130i corresponding to the gate electrode 130, and the channel layer 140, the resistance change layer 146, and/or the metal-containing layer 148 positioned in the recess portion 130r corresponding to the gate electrode 130 may constitute one memory cell. In an embodiment, the memory cell is configured as a resistive random access memory (RRAM) cell including the resistance change layer 146, and may store information using a resistance change of the resistance change layer 146 that occurs when a voltage is applied. A method of driving (i.e., operating) the semiconductor device 10 including memory cells configured as resistive random access memory cells as described above will be described in detail with reference to FIGS. 5A to 5D.

FIGS. 5A to 5D are diagrams for explaining an example method of driving the semiconductor device illustrated in FIG. 1. FIGS. 5A and 5B illustrate program (i.e., write) operations, FIG. 5C illustrates an erase operation, and FIG. 5D illustrates a read operation.

As illustrated in FIG. 5A, in a memory cell selected in a program operation, a voltage for the program operation is applied to the channel layer 140, and the gate electrode 130 is unselected or turned off. When the voltage for the program operation is applied to the channel layer 140, oxygen vacancies in the resistance change layer 146 may move to one side to form a current flow path having a low resistance. In this manner, when the gate electrode 130 is turned off and the resistance change layer 146 has a low resistance, the current moving along the channel layer 140 moves along the resistance change layer 146, the metal-containing layer 148, and the resistance change layer 146 in a path spaced apart from the gate electrode 130, and then moves back to the channel layer 140 located below as indicated by an arrow. As a result, the memory cell selected in the program operation stores data 1 (i.e., logic “1”) or is turned on.

On the other hand, as illustrated in FIG. 5B, in a memory cell that is not selected in the program operation, a voltage for the program operation is applied to the channel layer 140, but the gate electrode 130 is selected or turned on. When the gate electrode 130 is turned on, the current flows along the channel layer 140 in a path adjacent to the gate electrode 130 and does not flow to the resistance change layer 146 and the metal-containing layer 148 as indicated by an arrow. As a result, the memory cell unselected in the program operation stores data 0 (i.e., logic “0”) or is turned off.

As illustrated in FIG. 5C, in a memory cell selected in an erase operation, a voltage for the erase operation is applied to the channel layer 140 and the gate electrode 130 is unselected or turned off. In this manner, when the gate electrode 130 is turned off and the resistance change layer 146 has a low resistance, the current moving along the channel layer 140 moves along the resistance change layer 146, the metal-containing layer 148, and the resistance change layer 146 in a path spaced apart from the gate electrode 130, and then moves back to the channel layer 140 located above as indicated by an arrow. As a result, the memory cell selected in the erase operation stores data 0 or is turned off.

As illustrated in FIG. 5D, in a read operation, a voltage for the read operation is applied to the channel layer 140 and the gate electrode 130 is unselected or turned off. In this manner, when the gate electrode 130 is turned off and the resistance change layer 146 has a low resistance, the current moving along the channel layer 140 moves along a path including the resistance change layer 146, the metal-containing layer 148, and the resistance change layer 146 while being spaced apart from the gate electrode 130, and then moves back to the channel layer 140 located below as indicated by an arrow. As a result, data can be read from the memory cell in the read operation.

Although it is indicated in FIGS. 5A to 5D for illustrative purposes whether a voltage applied to the channel layer 140 is positive or negative, the embodiment is not limited thereto.

According to the embodiment, since the memory cells are configured as resistive random access memory cells, it is possible to prevent interference between neighboring memory cells. Accordingly, the thickness of the gate electrode 130 can be reduced, thereby increasing the number of gate electrodes 130 and increasing the capacity of the memory. On the other hand, if the memory cells are configured as charge trap flashes (CTFs) driven by storing charge unlike the embodiment, an interference phenomenon in which the charge stored in a memory cell escapes to a surrounding memory cell may occur. In the charge trap flashes, due to the large interference between the memory cells as described above, there is a limit in reducing the thickness of the gate electrode to increase the number of gate electrodes.

In this case, by placing the metal-containing layer 148 on the resistance change layer 146, oxygen is induced to move from the resistance change layer 146 to the metal-containing layer 148, thereby controlling oxygen vacancies in the resistance change layer 146. That is, the number, concentration, amount, or the like of oxygen vacancies in the resistance change layer 146 may be adjusted by adjusting the thickness and the material of the resistance change layer 146, the thickness and the material of the metal-containing layer 148, and the like. In addition, the thickness of the resistance change layer 146 may be adjusted by adjusting the thickness of the metal-containing layer 148. Since the oxygen vacancies in the resistance change layer 146 and the thickness of the resistance change layer 146 are factors for controlling the properties of the memory cell that is a resistive random access memory cell, the properties of the memory cell can be effectively controlled by the metal-containing layer 148 in the embodiment. Accordingly, the performance and efficiency of the semiconductor device 10 can be effectively improved with the simple structure. On the other hand, in a case where the metal-containing layer is not included unlike the embodiment, the thickness of the resistance change layer inevitably depends on the thickness of the channel layer and/or the gate electrode.

In particular, in a structure in which the channel structure CH is positioned in the through portion 124 (FIGS. 6A to 6D) extending in the vertical direction as in the embodiment, the resistance change layer 146 may be formed using an atomic layer deposition (ALD) process to stably form the channel structure CH in the through portion 124. Since deposition is performed layer by layer in the atomic layer deposition process, it is difficult to control the number of oxygen vacancies in the resistance change layer 146. The structure according to the embodiment may have a greater effect when the resistance change layer 146 is formed using the atomic layer deposition process. However, the embodiment is not limited thereto.

An example of a method for manufacturing the semiconductor device 10 having the above-described structure will be described in detail with reference to FIGS. 6A to 6F. Parts that have already been described will not be described in detail, and parts that have not been described will be described in detail.

FIGS. 6A to 6F are partial cross-sectional views illustrating intermediate processes in an example method of manufacturing the semiconductor device 10 of FIG. 1, according to an embodiment. The portion illustrated in FIG. 3 is mainly focused on in FIGS. 6A to 6F, and the method for manufacturing the semiconductor device 10 will be described mainly focused on the gate stack structure 120 and the channel structure CH formed in the cell area 100.

Referring to FIG. 6A, a horizontal insulating layer (reference label 116 in FIG. 1, hereinafter denoted by the same reference label) and a second horizontal conductive layer (reference label 114 in FIG. 1, hereinafter denoted by the same reference label) are formed on a second substrate (reference label 110 in FIG. 1), a stack structure 120s is formed by alternately stacking sacrificial insulating layers 130s and cell insulating layers 132, and then a penetration portion 124a of a through portion (reference label 124 in FIG. 6B, hereinafter denoted by the same reference label) penetrating through the stack structure 120s may be formed.

Here, the sacrificial insulating layers 130s may be layers to be replaced with gate electrodes (reference label 130 in FIG. 6F, hereinafter denoted by the same reference sign) or the like through a subsequent process, and at least a partial portion of the horizontal insulating layer 116 may be a layer to be replaced with a first horizontal conductive layer (reference label 112 in FIG. 1, hereinafter denoted by the same reference label) through a subsequent process. That is, the sacrificial insulating layers 130s may be formed to correspond to portions where the gate electrodes 130 or the like are to be formed, and the horizontal insulating layer 116 may be formed to include a portion where the first horizontal conductive layer 112 is to be formed.

The horizontal insulating layer 116 and/or the sacrificial insulating layers 130s may be formed of a material different from that of the cell insulating layers 132. For example, the cell insulating layers 132 may include silicon oxide, silicon nitride, silicon nitride oxide, a low dielectric constant material, or the like, and the sacrificial insulating layers 130s may include one of silicon, silicon oxide, silicon carbide, silicon nitride, and the like that is a material different from that of the cell insulating layers 132.

The penetration portion 124a of the through portion 124 may be a portion that elongates in a vertical (i.e., Z-axis) direction intersecting the second substrate 110 (e.g., a vertical direction perpendicular to the second substrate 110) (a Z-axis direction in the drawings). The penetration portion 124a may be formed by an etching process, e.g., an anisotropic etching process. The penetration portion 124a may be formed by etching the stack structure 120s in the vertical direction (i.e., Z-axis direction).

When viewed in a cross-sectional view, the overall side surface of the penetration portion 124a may be formed as a continuous inclined surface having an entirely constant slope so that the penetration portion 124a has a lateral width (e.g., X-axis and/or Y-axis direction) that gradually narrows toward the second substrate 110. Alternatively, the overall side surface of the penetration portion 124a may be formed as a vertical surface perpendicular to the second substrate 110. However, the embodiment is not limited to the above-described shape of the penetration portion 124a, and the penetration portion 124a may have any of various shapes as long as it penetrates through the stack structure 120s entirely.

In an embodiment, the stack structure 120s may include a first stack structure and a second stack structure corresponding to a first gate stack structure (reference label 120a in FIG. 1, hereinafter denoted by the same reference label) and a second gate stack structure (reference label 120b in FIG. 1, hereinafter denoted by the same reference label), respectively. The through portion 124 may include a first penetration portion formed by penetrating through the first stack structure to provide a partial portion of a space in which the first channel structure (reference label CH1 in FIG. 1) is to be formed, and a second penetration portion formed by penetrating through the second stack structure to provide a partial portion of a space in which the second channel structure (reference label CH2 in FIG. 1) is to be formed.

As an example, after forming the first stack structure and forming the first penetration portion, the second stack structure may be formed and then the second penetration portion may be formed. As another example, after forming the first stack structure and the second stack structure, and then forming the second penetration portion, the first penetration portion may be formed through the second penetration portion. The process for forming the stack structures and the penetration portions, the order in which the stack structures and the penetration portions are formed, and the like may be modified in various manners.

Subsequently, as illustrated in FIG. 6B, extension portions 124b of the through portion 124 may be formed by etching the sacrificial insulating layers 130s in a horizontal direction parallel to an upper surface of the second substrate 110. Accordingly, a partial portion of each of the plurality of sacrificial insulating layers 130s adjacent to the through portion 124 may be removed, such that recess portions 130r are formed to correspond to the plurality of sacrificial insulating layers 130s, respectively.

More specifically, the extension portions 124b may be formed by removing horizontally partial portions of the sacrificial insulating layers 130s exposed through the penetration portion 124a of the through portion 124. When an etching material is introduced through the penetration portion 124a, partial portions of the sacrificial insulating layers 130s adjacent to the penetration portion 124a may be etched in the horizontal direction, thereby forming extension portions 124b. As a result, the recess portions 130r may be formed. At this time, the etching may be performed upward and downward of the sacrificial insulating layers 130s as well, and the extension portions 124b may be formed to be slightly thicker than the sacrificial insulating layers 130s, but the embodiment is not limited thereto. Since the extension portions 124b are formed by etching the sacrificial insulating layers 130s in the horizontal direction through the penetration portion 124a as described above, a side surface of each of the extension portions 124b may have a relatively small slope, be convex toward the sacrificial insulating layer 130s or the gate electrode 130, or include a rounded portion.

The through portion 124 including the penetration portion 124a and the extension portions 124b may be a portion formed by penetrating through the stack structure 120s to provide a space in which the channel structure (reference label CH in FIG. 1) is to be formed.

Subsequently, as illustrated in FIG. 6C, a channel layer 140, a resistance change layer 146, and a preliminary metal-containing layer 148a are sequentially formed on a side surface of the through portion 124 entirely and continuously in the through portion 124. That is, the channel layer 140, the resistance change layer 146, and the preliminary metal-containing layer 148a may be sequentially formed in such a manner as to repeatedly extend in the vertical direction and in the horizontal direction on a side surface of the gate stack structure 120 including the plurality of recess portions 130r or in the through portion 124.

The channel layer 140, the resistance change layer 146, and the preliminary metal-containing layer 148a may be formed using an atomic layer deposition process or a chemical vapor deposition (CVD) process. As an example, in a case where the atomic layer deposition process is used, the channel layer 140, the resistance change layer 146, and the preliminary metal-containing layer 148a may be stably formed in the through portion 124 including the penetration portion 124a having a narrow and long shape and the extension portions 124b extending therefrom. However, the embodiment is not limited thereto, and any of various other processes may be applied.

As an example, the channel layer 140 may be formed by depositing a material constituting the channel layer 140 to a first thickness, performing a crystallization process, and then partially etching the deposited material to have a second thickness smaller than the first thickness. However, the embodiment is not limited thereto, and the channel layer 140 may be formed by any of various processes.

Subsequently, as illustrated in FIG. 6D, the preliminary metal-containing layer (reference label 148a in FIG. 6C, hereinafter denoted by the same reference label) may be partially removed to form a plurality of metal-containing layers 148 spaced apart from each other while individually corresponding to the plurality of recess portions 130r, respectively.

For example, the plurality of metal-containing layers 148 may be formed by etching the other side surface of the preliminary metal-containing layer 148a (FIG. 6C) located opposite to the stack structure 120s. At this time, the metal-containing layers 148 and/or the resistance change layer 146 may be etched so that the other side surfaces of the metal-containing layers 148 and the other side surface of the resistance change layer 146 located opposite to the stack structure 120s are positioned on the same plane (i.e., coplanar). The embodiment is not limited thereto, and the other side surfaces of the metal-containing layers 148 and the other side surface of the resistance change layer 146 may be positioned on different planes. As an etching process, wet etching or dry etching may be used.

Subsequently, as illustrated in FIG. 6E, a channel structure CH may be formed by forming a core insulating layer 142 and forming a channel pad (reference label 144 in FIG. 1) on the channel layer 140.

An upper isolation region (reference label 162 in FIG. 1, hereinafter denoted by the same reference label) may be formed by forming an upper isolation opening through an etching process using a mask layer and depositing an insulating material in the upper isolation opening. The process of forming the upper isolation region 162, the order in which the upper isolation region 162 is formed, and the like may be modified in various manners. The upper isolation region 162 may be formed before or after forming the channel structure CH.

Subsequently, as illustrated in FIG. 6F, the sacrificial insulating layers (reference label 130s in FIG. 6E, hereinafter denoted by the same reference label) may be removed, and gate insulating layers 130i and gate electrodes 130 may be formed in regions where the sacrificial insulating layers 130s were positioned. The gate insulating layers 130i and the gate electrodes 130 may be formed using an atomic layer deposition process or a chemical vapor deposition process.

For example, an opening (not explicitly illustrated) may be formed to penetrate through the stack structure (reference label 120s in FIG. 6E) in which the sacrificial insulating layers 130s and the cell insulating layers 132 are stacked. Such an opening may be formed in a region corresponding to the isolation structure (reference label 160 in FIG. 1, hereinafter denoted by the same reference label). By performing an etching process (e.g., a wet etching process) through the opening, the sacrificial insulating layers 130s may be selectively removed. Then, gate insulating layers 130i and gate electrodes 130 may be formed by burying an insulating material constituting the gate insulating layers 130i and a conductive material constituting the gate electrodes 130 in portions where the sacrificial insulating layers 130s are removed. In this case, the opening may be formed to expose the horizontal insulating layer 116. At least a partial portion of the horizontal insulating layer 116 may be removed in an etching process through the opening, and a first horizontal conductive layer 112 may be formed by burying a material constituting the first horizontal conductive layer 112. Then, an isolation structure 160 may be formed by filling the opening with an insulating material.

Thereafter, a first wiring unit (reference label 180 in FIG. 1) connected to the channel structure CH or the like may be further formed.

The manufacturing method using the stack structure 120s including sacrificial insulating layers 130s and cell insulating layers 132 is exemplified in FIGS. 6A to 6F, but the embodiment is not limited thereto. After a gate stack structure 120 is formed by stacking cell insulating layers 132 and gate electrodes 130, a through portion 124 may be formed, and then gate insulating layers 130i, a channel layer 140, a resistance change layer 146, metal-containing layers 148, a core insulating layer 142, etc. may be formed in the through portion 124.

According to the embodiment, the semiconductor device 10 having excellent performance and efficiency can be formed through the simple process.

Hereinafter, a semiconductor device according to an embodiment different from the above-described embodiment will be described in more detail with reference to FIGS. 7 and 8. Parts that are identical to or extremely similar to the parts that have already been described will not be described in detail, and the other parts will be described in detail.

FIG. 7 is an enlarged partial cross-sectional view illustrating a partial portion of a semiconductor device according to another embodiment.

Referring to FIG. 7, in the embodiment, the lateral width L of the recess portion 130r in the horizontal direction may be equal to the sum of the thickness T1 of the channel layer 140 and the thickness T2 of the resistance change layer 146. Accordingly, the side surface of the metal-containing layer 148 adjacent to the gate electrode 130 may be positioned on the same plane as (i.e., coplanar with) the side surface of the cell insulating layer 132 adjacent to the channel structure CH; that is, the side surface of the metal-containing layer 148 may be vertically aligned with the side surface of the cell insulating layer 132 adjacent to the channel structure CH.

The channel layer 140, the resistance change layer 146, the metal-containing layer 148, the resistance change layer 146, and the channel layer 140 may be sequentially positioned in the vertical direction (i.e., a Z-axis direction in the drawings) at a position corresponding to the gate electrode 130. In addition, a structure in which the channel layer 140, the resistance change layer 146, and the channel layer 140 are stacked in the vertical direction (i.e., a Z-axis direction in the drawings) may be formed in the recess portion 130r. That is, even when the metal-containing layer 148 is provided between the first horizontal portion and the second horizontal portion of the resistance change layer 146, the channel layer 140, the resistance change layer 146, and the channel layer 140 may be positioned inside the recess portion 130r without the metal-containing layer 148 inside the recess portion 130r. Accordingly, it is possible to minimize the width L of the recess portion 130r and the contact area between the resistance change layer 146 and the metal-containing layer 148, thereby greatly reducing the distribution of the operating voltage of the memory cell.

In an embodiment, in a memory cell selected in a program operation or in a read operation, the current may flow through the channel layer 140, the resistance change layer 146, the metal-containing layer 148, the resistance change layer 146, and the channel layer 140 sequentially as indicated by an arrow in FIG. 7. In an erase operation, the current may flow through the channel layer 140, the resistance change layer 146, the metal-containing layer 148, the resistance change layer 146, and the channel layer 140 in a direction opposite to that indicated by the arrow in FIG. 7. In a program operation, the current in an unselected memory cell may flow along the channel layer 140. However, the embodiment is not limited thereto.

FIG. 8 is an enlarged partial cross-sectional view illustrating a partial portion of a semiconductor device according to another embodiment.

Referring to FIG. 8, in the embodiment, a barrier layer 149 may be positioned between the channel layer 140 and the resistance change layer 146. Accordingly, the channel layer 140, the barrier layer 149, the resistance change layer 146, the metal-containing layer 148, the resistance change layer 146, the barrier layer 149, and the channel layer 140 may be sequentially positioned in the vertical direction (i.e., a Z-axis direction in the drawings) at a position corresponding to the gate electrode 130 or in the recess portion 130r.

The barrier layer 149 may include an insulating material, and may be positioned between the channel layer 140 and the resistance change layer 146. The barrier layer 149 is capable of preventing oxygen in the resistance change layer 146 from moving to the channel layer 140 and preventing over current, thereby preventing damage to the channel layer 140 and the resistance change layer 146. The barrier layer 149 may include a material that is chemically stable and has little interaction with the channel layer 140 and the resistance change layer 146. For example, the barrier layer 149 may include silicon oxide or aluminum oxide. As an example, if the barrier layer 149 is made of aluminum oxide, the barrier layer 149 may be more chemically stable.

The barrier layer 149 may have a smaller cross-sectional thickness than each of the channel layer 140, the resistance change layer 146, and/or the metal-containing layer 148. This is because, even though the barrier layer 149 has a small thickness, the thickness of the barrier layer 149 is sufficient to prevent movement of oxygen and prevent overcurrent. By making the thickness of the barrier layer 149 relatively small as described above, the thickness of the gate electrode 130 can be kept small even though the barrier layer 149 is provided.

In FIG. 8, it is exemplified that the metal change layer 148 is positioned in the recess portion 130r similarly to what is illustrated in FIG. 3. The metal change layer 148 may not be positioned in the recessed portion 130r as illustrated in FIG. 7 unlike what is illustrated in FIG. 8, the channel layer 140, the barrier layer 149, the resistance change layer 146, the barrier layer 149, and the channel layer 140 may be positioned in the vertical direction (i.e., a Z-axis direction in the drawings) in the recessed portion 130r. In addition, modifications may be made in various manners.

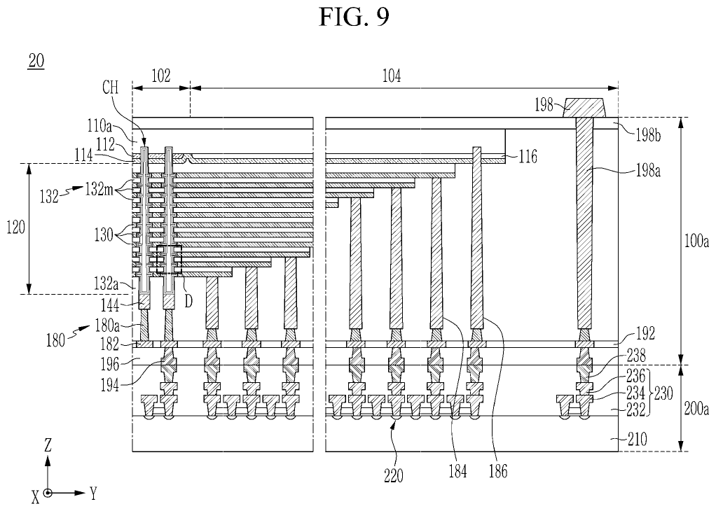

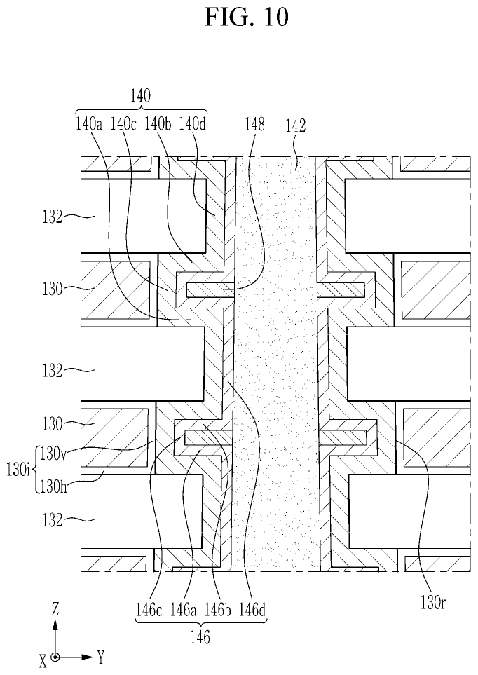

An additional embodiment different from the above-described embodiments will be described in detail with reference to FIGS. 9 and 10. With respect to the reference label identical or similar to those in the above-described embodiments, the description of the above-described embodiments may be identically applied, unless otherwise mentioned. Hereinafter, parts different from those in the above-described embodiments will be mainly described.

FIG. 9 is a schematic cross-sectional view illustrating a semiconductor device according to an additional embodiment. FIG. 10 is an enlarged partial cross-sectional view illustrating portion D of FIG. 9.

Referring to FIGS. 9 and 10, the semiconductor device 20 according to the embodiment may have a chip-to-chip (C2C) structure in which chips are bonded by a wafer bonding method. That is, the semiconductor device 20 may be manufactured by producing a lower chip including a circuit area 200a formed on a first substrate 210 and producing an upper chip including a cell area 100a formed on a second substrate 110a, and then bonding the lower chip and the upper chip to each other.

A first substrate 210, circuit elements 220, a first wiring unit 230, and first bonding structures 238 electrically connected to the first wiring unit 230 and positioned on a surface facing the cell area 100a may be provided in the circuit area 200a. A region other than the first bonding structures 238 may be covered by the first insulating layer 232 on the surface facing the cell area 100a. The term “covered” (or “covers” or “covering” or like terms) as may be used herein is intended to broadly refer to a material, layer or structure being on or over another material, layer or structure, but does not require the material, layer or structure to entirely cover the other material, layer or structure.

A second substrate 110a, a gate stack structure 120, a channel structure CH, a second wiring unit 180, and second bonding structures 194 electrically connected to the second wiring unit 180 and positioned on a surface facing the circuit area 200a may be provided in the cell area 100a. A region other than the second bonding structures 194 may be covered by an insulating layer 196.

In the embodiment, the second substrate 110a may be a semiconductor substrate including a semiconductor material. For example, the second substrate 110a may be a semiconductor substrate made of a semiconductor material, or may be a semiconductor substrate in which a semiconductor layer is formed on a base substrate. As an example, the second substrate 110a may be made of monocrystalline or polycrystalline silicon, germanium, silicon-germanium, silicon-on-insulator, germanium-on-insulator, or the like. Alternatively, the second substrate 110a may be formed of an insulating layer or a support member including an insulating material. This is because, after bonding the cell area 100a to the circuit area 200a, the semiconductor substrate provided in the cell area 100a may be removed to form an insulating layer or a support member including an insulating material.

In the gate stack structure 120, the gate electrodes 130 may include a lower gate electrode, a memory cell gate electrode, and an upper gate electrode sequentially positioned on the second substrate 110a in a direction from the second substrate 110a toward the circuit area 200a. That is, as illustrated in FIGS. 9 and 10, the components of the gate stack structure 120 may be sequentially stacked in a vertical (i.e., Z-axis) direction under the second substrate 110a in the drawings, such that the components are disposed in a structure in which the gate stack structure 120 illustrated in FIGS. 1 to 4 is vertically inverted (i.e., flipped). The channel structure CH including a channel layer 140, a resistance change layer 146, and a metal-containing layer 148 sequentially stacked through the gate stack structure 120 may also have a structure in which the channel structure CH illustrated in FIGS. 1 to 4 is vertically inverted. Accordingly, when viewed in a cross-sectional view, the channel structure CH may have an inclined side surface having a lateral width (i.e., in the X-axis and/or Y-axis direction in the drawings) that becomes narrower as the channel structure CH extends vertically toward the second substrate 110a from the circuit area 200a. In addition, a channel pad 144 and a second wiring unit 180 positioned on the gate stack structure 120 may be positioned adjacent to the circuit area 200a.

For example, the first bonding structures 238 and/or the second bonding structures 194 may be made of aluminum, copper, tungsten, or an alloy thereof. As an example, the first and second bonding structures 238 and 194 may include copper, such that the cell area 100a and the circuit area 200a are bonded to each other by copper-to-copper bonding (for example, bonded in direct contact with each other).

Although it is exemplified in FIG. 9 that the gate stack structure 120 is formed as a single gate stack structure, the gate stack structure 120 may include a plurality of gate stack structures as illustrated in FIG. 1. The descriptions of the gate stack structure 120 and the channel structure CH provided with reference to FIGS. 1 to 3, FIGS. 4A and 4B, FIGS. 5A to 5D, FIGS. 6A to 6F, and FIGS. 7 and 8 may be identically applied, except what are otherwise described. In FIG. 9, it is exemplified that the structure for electrical connection between the channel structure CH and the horizontal conductive layers 112 and 114 and/or the second substrate 110a is the same as that in FIG. 1. However, the embodiment is not limited thereto, and the structure for electrical connection between the channel structure CH and the horizontal conductive layers 112 and 114 and/or the second substrate 110a may be modified in various manners.

The semiconductor device 20 according to an embodiment may include an input/output pad 198 and an input/output connection wire 198a electrically connected thereto. The input/output connection wire 198a may be electrically connected to some of the second bonding structures 194. The input/output pad 198 may be positioned on, for example, an insulating film 198b covering an outer surface of the second substrate 110a. In a certain embodiment, a separate input/output pad electrically connected to the circuit area 200a may be provided.

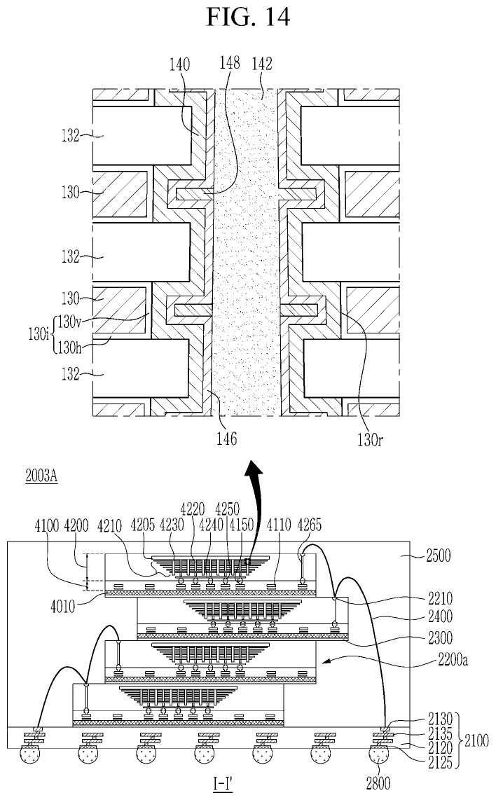

As an example, the circuit area 200a and the cell area 100a may be portions corresponding to the first structure 1100F and the second structure 1100S, respectively, of the semiconductor device 1100 included in the electronic system 1000 illustrated in FIG. 11. Alternatively, the circuit area 200a and the cell area 100a may be portions including a first structure 4100 and a second structure 4200, respectively, of a semiconductor chip 2200a illustrated in FIG. 14.

An example of an electronic system including the above-described semiconductor device will be described in detail below.

FIG. 11 is a schematic diagram illustrating an electronic system including a semiconductor device according to an embodiment.

Referring to FIG. 11, the electronic system 1000 according to the embodiment may include a semiconductor device 1100 and a controller 1200 electrically connected to the semiconductor device 1100. The electronic system 1000 may be a storage device including one or more semiconductor devices 1100 or an electronic device including the storage device. For example, the electronic system 1000 may be a solid state drive (SSD) device, a universal serial bus (USB), a computing system, a medical device, or a communication device including one or more semiconductor devices 1100.

The semiconductor device 1100 may be a non-volatile memory device, and may be, for example, a NAND flash memory device described with reference to FIGS. 1 to 3, FIGS. 4A and 4B, FIGS. 5A to 5D, FIGS. 6A to 6F, and FIGS. 7 to 10. The semiconductor device 1100 may include a first structure 1100F and a second structure 1100S disposed on the first structure 1100F. In an embodiment, the first structure 1100F may be disposed next to the second structure 1100S. The first structure 1100F may be a peripheral circuit structure including a decoder circuit 1110, a page buffer 1120, and a logic circuit 1130. The second structure 1100S may be a memory cell structure including bit lines BL, a common source line CSL, word lines WL, first and second gate upper lines UL1 and UL2, first and second gate lower lines LL1 and LL2, and memory cell strings CSTR between the bit lines BL and the common source line CSL.

In the second structure 1100S, each of the memory cell strings CSTR may include lower transistors LT1 and LT2 adjacent to the common source line CSL, upper transistors UT1 and UT2 adjacent to the bit lines BL, and a plurality of memory cell transistors MCT disposed between the lower transistors LT1 and LT2 and the upper transistors UT1 and UT2. The number of lower transistors LT1 and LT2 and the number of upper transistors UT1 and UT2 may be variously modified in certain embodiments.

In an embodiment, the lower transistors LT1 and LT2 may include ground select transistors, and the upper transistors UT1 and UT2 may include string select transistors. The first and second gate lower lines LL1 and LL2 may be gate electrodes of the lower transistors LT1 and LT2, respectively. The word lines WL may be gate electrodes of the memory cell transistors MCT, and the gate upper lines UL1 and UL2 may be gate electrodes of the upper transistors UT1 and UT2, respectively.

The common source line CSL, the first and second gate lower lines LL1 and LL2, the word lines WL, and the first and second gate upper lines UL1 and UL2 may be electrically connected to the decoder circuit 1110 through first connection wires 1115 extending from the inside of the first structure 1100F to the second structure 1100S. The bit lines BL may be electrically connected to the page buffer 1120 through second connection wires 1125 extending from the inside of the first structure 1100F to the second structure 1100S.

In the first structure 1100F, the decoder circuit 1110 and the page buffer 1120 may execute a control operation with respect to at least one memory cell transistor selected from among the plurality of memory cell transistors MCT. The decoder circuit 1110 and the page buffer 1120 may be controlled by the logic circuit 1130. The semiconductor device 1100 may communicate with the controller 1200 through one or more input/output pads 1101 electrically connected to the logic circuit 1130. The input/output pad 1101 may be electrically connected to the logic circuit 1130 through one or more corresponding input/output connection wires 1135 extending from the inside of the first structure 1100F to the second structure 1100S.

The controller 1200 may include a processor 1210, a NAND controller 1220, and a host interface (I/F) 1230. In a certain embodiment, the electronic system 1000 may include a plurality of semiconductor devices 1100, and in this case, the controller 1200 may control the plurality of semiconductor devices 1100.

The processor 1210 may control an overall operation of the electronic system 1000 including the controller 1200. The processor 1210 may operate according to predetermined firmware and access the semiconductor device 1100 by controlling the NAND controller 1220. The NAND controller 1220 may include a NAND interface (I/F) 1221 that processes communication with the semiconductor device 1100. Through the NAND interface 1221, a control command for controlling the semiconductor device 1100, data to be written to the memory cell transistors MCT of the semiconductor device 1100, data to be read from the memory cell transistors MCT of the semiconductor device 1100, and the like may be conveyed. The host interface 1230 may provide a function of communication between the electronic system 1000 and an external host. Upon receiving a control command from the external host through the host interface 1230, the processor 1210 may control the semiconductor device 1100 in response to the control command.

FIG. 12 is a schematic perspective view illustrating an electronic system including a semiconductor device according to an embodiment.

Referring to FIG. 12, the electronic system 2000 according to an embodiment may include a main board 2001, a controller 2002 mounted on the main board 2001, one or more semiconductor packages 2003, and a DRAM 2004. The semiconductor packages 2003 and the DRAM 2004 may be connected to the controller 2002 through wiring patterns 2005 formed on the main board 2001.

The main board 2001 may include a connector 2006 including a plurality of pins to be coupled to an external host. The number of the plurality of pins and the arrangement of the plurality of pins in the connector 2006 may vary depending on a communication interface between the electronic system 2000 and the external host. In an embodiment, the electronic system 2000 may communicate with the external host according to any one of the interfaces such as universal serial bus (USB), peripheral component interconnect express (PCI-Express), serial advanced technology attachment (SATA), and M-Phy for universal flash storage (UFS). In an embodiment, the electronic system 2000 may be operated by power supplied from the external host through the connector 2006. The electronic system 2000 may further include a power management integrated circuit (PMIC) that distributes the power supplied from the external host to the controller 2002 and the semiconductor packages 2003.

The controller 2002 may write data to the semiconductor packages 2003 or read data from the semiconductor packages 2003, and may improve the operating speed of the electronic system 2000.

The DRAM 2004 may be a buffer memory for mitigating a speed difference between the semiconductor package(s) 2003, which is a data storage space, and the external host. The DRAM 2004 included in the electronic system 2000 may also operate as a kind of cache memory, and may provide a space for temporarily storing data in an operation for controlling the semiconductor package(s) 2003. In a case where the DRAM 2004 is included in the electronic system 2000, the controller 2002 may further include a DRAM controller for controlling the DRAM 2004 in addition to the NAND controller for controlling the semiconductor packages 2003.

The semiconductor packages 2003 may include first and second semiconductor packages 2003a and 2003b spaced apart from each other. Each of the first and second semiconductor packages 2003a and 2003b may be a semiconductor package including a plurality of semiconductor chips 2200. Each of the first and second semiconductor packages 2003a and 2003b may include a package board 2100, semiconductor chips 2200 disposed on the package board 2100, an adhesive layer 2300 disposed on a lower surface of each of the semiconductor chips 2200, connection structures 2400 electrically connecting the semiconductor chips 2200 to the package board 2100, and a molding layer 2500 covering the semiconductor chips 2200 and the connection structures 2400 on the package board 2100.

The package board 2100 may be a printed circuit board including a package upper pad 2130. Each of the semiconductor chips 2200 may include an input/output pad 2210. The input/output pad 2210 may correspond to the input/output pad 1101 of FIG. 11. Each of the semiconductor chips 2200 may include a gate stack structure 3210 and a channel structure 3220. Each of the semiconductor chips 2200 may include the semiconductor device described with reference to FIGS. 1 to 3, FIGS. 4A and 4B, FIGS. 5A to 5D, FIGS. 6A to 6F, and FIGS. 7 to 10.

In an embodiment, the connection structure 2400 may be a bonding wire electrically connecting the input/output pad 2210 and the package upper pad 2130 to each other. Accordingly, in each of the first and second semiconductor packages 2003a and 2003b, the semiconductor chips 2200 may be electrically connected to each other in a wire bonding manner, and may be electrically connected to the package upper pad 2130 of the package board 2100 in a wire bonding manner. In a certain embodiment, in each of the first and second semiconductor packages 2003a and 2003b, the semiconductor chips 2200 may be electrically connected to each other by a connection structure including a through silicon via (TSV), rather than the connection structure 2400 of the wire bonding type.

In an embodiment, the controller 2002 and the semiconductor chips 2200 may be included in one package. For example, the controller 2002 and the semiconductor chips 2200 may be mounted on a separate interposer board different from the main board 2001, and the controller 2002 and the semiconductor chips 2200 may be connected to each other by wires formed on the interposer board.

FIGS. 13 and 14 are schematic cross-sectional views each illustrating a semiconductor package according to an embodiment. Each of FIGS. 13 and 14 explains an embodiment of the semiconductor package 2003 of FIG. 12, and conceptually illustrates a region obtained when the semiconductor package 2003 of FIG. 12 is cut along line I-I′.

Referring to FIG. 13, in the semiconductor package 2003, the package board 2100 may be a printed circuit board. The package board 2100 may include a package board body 2120, a package upper pad 2130 disposed on an upper surface of the package board body 2120, a lower pad 2125 disposed on or exposed through a lower surface of the package board body 2120, and an internal wire 2135 electrically connecting the upper pad 2130 and the lower pad 2125 to each other inside the package board body 2120. The upper pad 2130 may be electrically connected to the connection structure 2400. The lower pad 2125 may be connected to the wiring pattern 2005 of the main board 2010 of the electronic system 2000 through a conductive connection unit 2800 as illustrated in FIG. 12.

Each of the semiconductor chips 2200 may include a semiconductor substrate 3010 and a first structure 3100 and a second structure 3200 sequentially stacked on the semiconductor substrate 3010. The first structure 3100 may include a peripheral circuit area including peripheral wires 3110. The second structure 3200 may include a common source line 3205, a gate stack structure 3210 disposed on the common source line 3205, channel structures 3220 and isolation structures 3230 penetrating through the gate stack structure 3210, bit lines 3240 electrically connected to the channel structures 3220, and gate connection wires electrically connected to word lines (reference sign WL in FIG. 11) of the gate stack structure 3210.

The semiconductor chip 2200 or the semiconductor device according to the embodiment may include a metal-containing layer 148 or an oxygen vacancy donating layer to improve performance and efficiency of the semiconductor device.

Each of the semiconductor chips 2200 may include a through wire 3245 electrically connected to the peripheral wire 3110 of the first structure 3100 and extending into the second structure 3200. The through wire 3245 may pass through the gate stack structure 3210 and may be further disposed outside the gate stack structure 3210. Each of the semiconductor chips 2200 may further include an input/output connection wire 3265 electrically connected to the peripheral wire 3110 of the first structure 3100 and extending into the second structure 3200, and an input/output pad 2210 electrically connected to the input/output connection wire 3265.

In an embodiment, the plurality of semiconductor chips 2200 in the semiconductor package 2003 may be electrically connected to each other by a connection structure 2400 in a wire bonding manner. As another example, the plurality of semiconductor chips 2200 or a plurality of parts constituting the plurality of semiconductor chips 2200 may be electrically connected to each other by a connection structure including a through silicon via (TSV).

Referring to FIG. 14, in a semiconductor package 2003A, each of semiconductor chips 2200a may include a semiconductor substrate 4010, a first structure 4100 disposed on the semiconductor substrate 4010, and a second structure 4200 bonded to the first structure 4100 in a wafer bonding manner on the first structure 4100.

The first structure 4100 may include a peripheral circuit area including peripheral wires 4110 and first bonding structures 4150. The second structure 4200 may include a common source line 4205, a gate stack structure 4210 between the common source line 4205 and the first structure 4100, channel structures 4220 and isolation structures 4230 penetrating through the gate stack structure 4210, and second bonding structures 4250 electrically connected to the channel structures 4220 and word lines (reference label WL in FIG. 11, hereinafter denoted by the same reference label) of the gate stack structure 4210, respectively. For example, the second bonding structures 4250 may be electrically connected to the channel structures 4220 and the word lines WL through bit lines 4240 electrically connected to the channel structures 4220 and gate connection wires electrically connected to the word lines WL, respectively. The first bonding structures 4150 of the first structure 4100 and the second bonding structures 4250 of the second structure 4200 may be bonded in contact with each other. A portion where the first bonding structure 4150 and the second bonding structure 4250 are bonded to each other may be formed of, for example, copper (Cu).

The semiconductor chip 2200 or the semiconductor device according to the embodiment may include a metal-containing layer 148 or an oxygen vacancy donating layer to improve its performance and efficiency

Each of the semiconductor chips 2200a may further include an input/output pad 2210 and an input/output connection wire 4265 disposed under the input/output pad 2210. The input/output connection wire 4265 may be electrically connected to some of the second bonding structures 4250.

In an embodiment, the plurality of semiconductor chips 2200a in the semiconductor package 2003A may be electrically connected to each other by a connection structure 2400 in a wire bonding manner. As another example, the plurality of semiconductor chips 2200 or a plurality of parts constituting the plurality of semiconductor chips 2200 may be electrically connected to each other by a connection structure including a through silicon via.

Although the embodiments of the present disclosure have been described in detail above, the scope of the present disclosure is not limited thereto, and various modifications and improvements made by those skilled in the art using the basic concept of the present disclosure defined in the following claims also fall within the scope of the present disclosure.

What is claimed is:

1. A semiconductor device, comprising:
a gate stack structure including a plurality of gate electrodes and a plurality of insulating layers alternately stacked on a substrate in a first direction perpendicular to an upper surface of the substrate; and
a channel structure including a portion penetrating through the gate stack structure and extending in the first direction, the channel structure including a channel layer, a resistance change layer, and a metal-containing layer sequentially stacked, the metal-containing layer including a metal or a metal compound.

2. The semiconductor device of claim 1, wherein
the resistance change layer comprises a metal oxide containing a first metal and oxygen, and
a Gibbs free energy of oxidation reaction of a second metal included in the metal-containing layer is equal to or less than a Gibbs free energy of oxidation reaction of the first metal.

3. The semiconductor device of claim 1, wherein
the metal-containing layer includes at least one of hafnium (Hf), titanium (Ti), zirconium (Zr), lanthanum (La), tantalum (Ta), aluminum (Al), nickel (Ni), tungsten (W), copper (Cu), gold (Au), ruthenium (Ru), platinum (Pt), titanium nitride (TiN), or tantalum nitride (TaN).

4. The semiconductor device of claim 3, wherein
the metal-containing layer includes at least one of titanium, tungsten, titanium nitride, or tantalum nitride.

5. The semiconductor device of claim 1, wherein
the metal-containing layer does not include oxygen or has a lower oxygen content than the resistance change layer.

6. The semiconductor device of claim 5, wherein
a ratio of the oxygen content of the metal-containing layer to the oxygen content of the resistance change layer is 10% or less.

7. The semiconductor device of claim 1, wherein
the metal-containing layer includes oxygen at least in a portion of the metal-containing layer adjacent to the resistance change layer, and
the metal-containing layer is configured such that the oxygen content of the metal-containing layer decreases with increasing distance from the resistance change layer.

8. The semiconductor device of claim 1, wherein
the channel structure includes a portion in which the channel layer, the resistance change layer, the metal-containing layer, the resistance change layer, and the channel layer are sequentially positioned in the first direction.

9. The semiconductor device of claim 1, wherein
a plurality of recess portions corresponding to the plurality of gate electrodes, respectively, are provided in a side surface of the gate stack structure adjacent to the channel structure, and
the channel structure includes a portion in which the channel layer, the resistance change layer, the metal-containing layer, the resistance change layer, and the channel layer are sequentially positioned in the first direction at a portion of the channel structure where each of the recess portions is positioned.

10. The semiconductor device of claim 1, wherein
a plurality of recess portions corresponding to the plurality of gate electrodes, respectively, are in a side surface of the gate stack structure adjacent to the channel structure,
the channel layer and the resistance change layer are continuously positioned along the side surface of the gate stack structure including the plurality of recess portions, and
the metal-containing layer includes a plurality of metal-containing layers individually formed to correspond to the plurality of recess portions, respectively.

11. The semiconductor device of claim 10, wherein
the metal-containing layer is on a side surface of the resistance change layer in a second direction, perpendicular to the first direction, to at least partially fill a space between portions of the resistance change layers in the first direction, and
a side surface of the metal-containing layer opposite to the side surface of the gate stack structure adjacent to the channel structure and the side surface of the resistance change layer are aligned with one another in the first direction.

12. The semiconductor device of claim 1, wherein
the metal-containing layer has a cross-sectional thickness equal to or greater than a cross-sectional thickness of the resistance change layer.

13. The semiconductor device of claim 1, wherein
a plurality of recess portions corresponding to the plurality of gate electrodes, respectively, are provided in a side surface of the gate stack structure adjacent to the channel structure, and
the channel layer, the resistance change layer, and the metal-containing layer are in each of the recess portions.

14. The semiconductor device of claim 1, wherein
a plurality of recess portions corresponding to the plurality of gate electrodes, respectively, are in a side surface of the gate stack structure adjacent to the channel structure, and
the channel layer and the resistance change layer are in each of the recess portions.

15. The semiconductor device of claim 1, further comprising
a barrier layer between the channel layer and the resistance change layer.

16. The semiconductor device of claim 15, wherein
the barrier layer includes silicon oxide or aluminum oxide, and
the barrier layer has a cross-sectional thickness smaller than a cross-sectional thickness of the channel layer, the resistance change layer, or the metal-containing layer.

17. The semiconductor device of claim 1, wherein
the channel layer includes at least one of a single semiconductor material, an oxide semiconductor material, or a two-dimensional semiconductor material.

18. The semiconductor device of claim 1, further comprising
a gate insulating layer including portions extending in a second direction, perpendicular to the first direction, between upper and lower portions of each of the gate electrodes and the insulating layers, and an extension portion extending in the first direction between a side surface of the gate electrode and the channel layer.

19. A semiconductor device including a resistive random access memory cell, the semiconductor device comprising:
a gate stack structure including a plurality of gate electrodes and a plurality of insulating layers alternately stacked on a substrate in a first direction perpendicular to an upper surface of the substrate; and
a channel structure including a portion penetrating through the gate stack structure and extending in the first direction, the channel structure including a channel layer, a resistance change layer, and an oxygen-vacancy donor layer sequentially stacked, the oxygen-vacancy donor layer configured to receive oxygen from the resistance change layer and to provide oxygen vacancies to the resistance change layer to control the oxygen vacancies in the resistance change layer.

20. An electronic system, comprising:
a main board;
a semiconductor device on the main board; and
a controller electrically connected to the semiconductor device on the main board,
wherein the semiconductor device includes:
a gate stack structure including a plurality of gate electrodes and a plurality of insulating layers alternately stacked on a substrate in a first direction perpendicular to an upper surface of the substrate; and
a channel structure including a portion penetrating through the gate stack structure and extending in the first direction, and the channel structure including a channel layer, a resistance change layer, and a metal-containing layer sequentially stacked, the metal-containing layer including metal or metal nitride.
